(19) United States
(12) Patent Application Publication
(10) Pub. No.: US 2023/0352640 A1
(43) Pub. Date: Nov. 2, 2023

(54) DISPLAY DEVICE

(71) Applicant: SAMSUNG DISPLAY CO., LTD., Yongin-si, Gyeonggi-do (KR)

(72) Inventors: Chul Jong YOO, Yongin-si, Gyeonggi-do (KR); Dong Eon LEE, Yongin-si, Gyeonggi-do (KR); Myeong Hee KIM, Yongin-si, Gyeonggi-do (KR); Hoo Keun PARK, Yongin-si, Gyeonggi-do (KR); Byung Ju LEE, Yongin-si, Gyeonggi-do (KR); So Young LEE, Yongin-si, Gyeonggi-do (KR); Seung Geun LEE, Yongin-si, Gyeonggi-do (KR); Seung A LEE, Yongin-si, Gyeonggi-do (KR); Jong Won LEE, Yongin-si, Gyeonggi-do (KR); Ji Hyun HAM, Yongin-si, Gyeonggi-do (KR)

(73) Assignee: SAMSUNG DISPLAY CO., LTD., Yongin-si, Gyeonggi-do (KR)

(21) Appl. No.: 18/022,402

(22) PCT Filed: Aug. 3, 2021
(86) PCT No.: PCT/KR2021/010180

§ 371 Date: Feb. 21, 2023

(30) Foreign Application Priority Data
Aug. 21, 2020 (KR) 10-2020-0105578

(51) Int. Cl. H01L 33/60; H01L 25/16

(52) U.S. Cl. CPC H01L 33/60; H01L 25/167

(57) ABSTRACT

A includes a substrate including a plurality of pixels, a plurality of transistors disposed on the substrate, a passivation layer overlapping the plurality of transistors, a first electrode and a second electrode disposed on the passivation layer and spaced apart from each other, an insulating layer disposed on the first electrode and the second electrode, a plurality of light emitting elements disposed between the first electrode and the second electrode on the insulating layer and electrically connected to the first electrode and the second electrode, and an insulating reflective layer disposed between the passivation layer and the plurality of light emitting elements.

### CROSS-REFERENCE TO RELATED APPLICATION(S)

This application is a national entry of International Application No. PCT/KR2021/010180, filed on Aug. 3, 2021, which claims under 35 U.S.C. § 119(a) and 365(b) priority to and benefits of Korean Patent Application No. 10-2020-0105578, filed on Aug. 21, 2020 in the Korean Intellectual Property Office, the entire contents of which are incorporated herein by reference.

### BACKGROUND

### 1. Technical Field

The disclosure relates to a display device.

### 2. Description of the Related Art

As interest in information display increases, research and development for display devices continues.

### SUMMARY

An aspect of the disclosure is to provide a display device with improved light emitting efficiency.

Aspects of the disclosure are not limited to the aspect mentioned above, and other technical aspects that are not mentioned may be clearly understood to a person of ordinary skill in the art using the following description.

A display device according to an embodiment may include a substrate including a plurality of pixels, a plurality of transistors disposed on the substrate, a passivation layer overlapping the plurality of transistors, a first electrode and a second electrode that are disposed on the passivation layer and spaced apart from each other, an insulating layer disposed on the first electrode and the second electrode, a plurality of light emitting elements disposed between the first electrode and the second electrode on the insulating layer and electrically connected to the first electrode and the second electrode, and an insulating reflective layer disposed between the passivation layer and the plurality of light emitting elements.

The insulating reflective layer may be disposed between the passivation layer and the insulating layer.

A surface of the insulating reflective layer may be in physical contact with the passivation layer, and another surface of the insulating reflective layer may be in physical contact with the insulating layer.

The display device may further include a bank disposed between the passivation layer and the first electrode and the second electrode, wherein the insulating reflective layer may be disposed between the passivation layer and the bank.

The insulating reflective layer may be disposed on a front surface of the passivation layer.

The insulating reflective layer may be disposed between the insulating layer and the plurality of light emitting elements.

The plurality of light emitting elements may be directly disposed on the insulating reflective layer.

The insulating reflective layer may include a plurality of first layers and second layers having different refractive indexes, and the first layers and second layers may be alternately stacked on each other.

The plurality of first layers and second layers may have different thicknesses.

The plurality of first layers may include a silicon oxide (SiOx), and the plurality of second layers may include a silicon nitride (SiNx).

The insulating reflective layer may include five or more of the plurality of first layers and five or more of the plurality of second layers.

The insulating reflective layer may include at least one of a barium sulfate (BaSO4), a lead carbonate (PbCO3), a titanium oxide (TiOx), a silicon oxide (SiOx), a zinc oxide (ZnOx), and an aluminum oxide (AlxOy).

The plurality of light emitting elements may include a first light emitting element emitting a first color, a second light emitting element emitting a second color, and a third light emitting element emitting a third color.

The insulating reflective layer may include a first insulating reflective layer disposed under the first light emitting element, a second insulating reflective layer disposed under the second light emitting element, and a third insulating reflective layer disposed under the third light emitting element, and the first to third insulating reflective layers may have different thicknesses.

The first color may be red, the second color may be green, and the third color may be blue.

A thickness of the first insulating reflective layer may be thicker than a thickness of the third insulating reflective layer.

A display device according to another embodiment may include a plurality of pixels, a plurality of transistors disposed on the substrate, a passivation layer overlapping the plurality of transistors, a first electrode and a second electrode that are disposed on the passivation layer and spaced apart from each other, an insulating reflective layer disposed on the first electrode and the second electrode, and a plurality of light emitting elements disposed between the first electrode and the second electrode on the insulating reflective layer and electrically connected to the first electrode and the second electrode. The insulating reflective layer may include a plurality of first layers and second layers having different refractive indexes, and the plurality of first layers and the plurality of second layers may be alternately stacked on each other.

The insulating reflective layer may be directly disposed on the first electrode and the second electrode.

The plurality of light emitting elements may be directly disposed on the insulating reflective layer.

A display device according to another embodiment may include a substrate including a plurality of pixels, a plurality of transistors disposed on the substrate, an insulating reflective layer overlapping the plurality of transistors, a first electrode and a second electrode that are disposed on the insulating reflective layer and spaced apart from each other, and a plurality of light emitting elements disposed between the first electrode and the second electrode and electrically connected to the first electrode and the second electrode. The insulating reflective layer may include a plurality of first layers and second layers having different refractive indexes, and the plurality of first layers and second layers may be alternately stacked on each other.

The plurality of first layers and second layers may include an organic insulating material.

Particularities of other embodiments are included in the detailed description and drawings.

According to embodiments of the disclosure, since an insulating reflective layer is disposed under a light emitting element, light emitted to a lower portion of the light emitting element may be reflected by the insulating reflective layer to be emitted in a front direction of a display panel. Accordingly, since an amount of light lost to a lower portion of the display panel may be minimized, front light output efficiency may be improved.

Effects of embodiments of the disclosure are not limited by what is illustrated in the above, and additional effects are included in the specification.

### BRIEF DESCRIPTION OF THE DRAWINGS

FIG. 1 and FIG. 2 illustrate a schematic perspective view and a schematic cross-sectional view of a light emitting element according to an embodiment.

FIG. 3 and FIG. 4 illustrate a schematic perspective view and a schematic cross-sectional view of a light emitting element according to another embodiment.

FIG. 5 illustrates a schematic perspective view of a light emitting element according to another embodiment.

FIG. 6 illustrates a schematic cross-sectional view of a light emitting element according to another embodiment.

FIG. 7 illustrates a schematic perspective view of a light emitting element according to another embodiment.

FIG. 8 illustrates a schematic plan view of a display device according to an embodiment.

FIG. 9 to FIG. 13 illustrate schematic circuit diagrams of a pixel according to an embodiment.

FIG. 14 and FIG. 15 illustrate schematic plan views of a pixel according to an embodiment.

FIG. 16 to FIG. 18 illustrate schematic cross-sectional views of a pixel according to an embodiment.

FIG. 19 illustrates a schematic cross-sectional view of an insulating reflective layer according to an embodiment.

FIG. 20 illustrates a schematic cross-sectional view of a display device according to another embodiment.

FIG. 21 illustrates a schematic cross-sectional view of a display device according to another embodiment.

FIG. 22 illustrates a schematic cross-sectional view of a display device according to another embodiment.

FIG. 23 illustrates a schematic cross-sectional view of a display device according to another embodiment.

FIG. 24 illustrates a schematic cross-sectional view of a display device according to another embodiment.

### DETAILED DESCRIPTION OF THE EMBODIMENTS

Advantages and features of the disclosure and methods of accomplishing the same may be understood more readily by reference to the following detailed description of embodiments and the accompanying drawings. The disclosure may, however, be embodied in different forms and should not be construed as limited to the embodiments set forth herein. The embodiments are provided so that this disclosure will be thorough and complete, and will fully convey the scope of the disclosure to those skilled in the art.

The terms used herein are for the purpose of describing particular embodiments only and are not intended to be limiting. As used herein, the singular forms “a”, “an” and “the” are intended to include the plural forms as well, unless the context clearly indicates otherwise. It will be further understood that the terms “comprise” and/or “comprising”, “include” or “including”, and “have” or “having”, when used in the disclosure, specify the presence of stated elements, steps, operations, and/or devices, but do not preclude the presence or addition of one or more other elements, steps, operations, and/or devices.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

It is to be understood that when an element is referred to as being “connected to” or “coupled with” another element, it may be directly connected to or coupled with another element, but there may also be one or more intervening elements present.

It will be understood that the terms “connected to” or “coupled to” may include a physical or electrical connection or coupling.

It will be understood that when an element or a layer is referred to as being “on” another element or layer, it can be directly on another element or layer, or one or more intervening elements or layers may also be present. Throughout the specification, the same reference numerals denote the same constituent elements.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap,” “overlapped,” and “overlapping” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

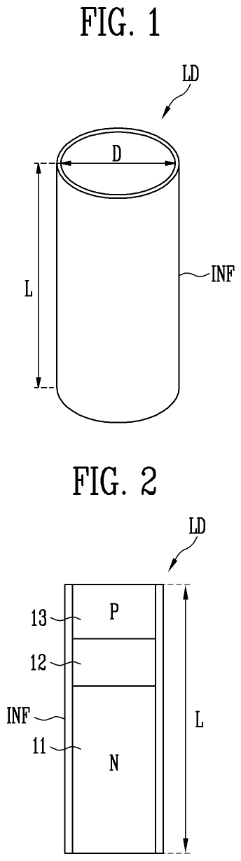

FIG. 1 and FIG. 2 illustrate a schematic perspective view and a schematic cross-sectional view of a light emitting element according to an embodiment. In FIG. 1 and FIG. 2, a cylindrical rod-shaped light emitting element LD is illustrated, but a type and/or shape of the light emitting element LD is not limited thereto.

Referring to FIG. 1 and FIG. 2, the light emitting element LD may include a first semiconductor layer 11 and a second semiconductor layer 13, and an active layer 12 interposed between the first and second semiconductor layers 11 and 13. For example, the light emitting element LD may be configured of a stacked body in which the first semiconductor layer 11, the active layer 12 and the second semiconductor layer 13 are sequentially stacked along a direction.

In some embodiments, the light emitting element LD may be provided to have a rod shape extending along a direction. The light emitting element LD may have an end portion and another end portion along a direction.

In some embodiments, one of the first and second semiconductor layers 11 and 13 may be disposed at an end portion of the light emitting element LD, and the other of the first and second semiconductor layers 11 and 13 may be disposed at another end portion of the light emitting element LD.

In some embodiments, the light emitting element LD may be a rod-shaped light emitting diode manufactured in a rod shape. Here, the rod shape includes a rod-like shape or a bar-like shape, of which a longitudinal direction may be longer than a width direction thereof (for example, with an aspect ratio greater than 1), such as a cylinder or polygonal column, and a shape of a cross section thereof is not particularly limited. For example, the length L of the light emitting element LD may be larger than a diameter D thereof (or a width of a lateral cross-section thereof).

In some embodiments, the light emitting element LD may have a size as small as a nanometer scale to a micrometer scale, for example, a diameter D and/or a length L ranging from about 100 nm to about 10 um. However, the size of the light emitting element LD is not limited thereto. For example, the size of the light emitting element LD may be variously changed according to design conditions of various devices using a light emitting device using the light emitting element LD as a light source, for example, a display device.

The first semiconductor layer 11 may include at least one n-type semiconductor material. For example, the first semiconductor layer 11 may include a semiconductor material of at least one of InAlGaN, GaN, AlGaN, InGaN, AlN, and InN, and may include a n-type semiconductor material doped with a first conductive dopant such as Si, Ge, Sn, and/or the like.

The active layer 12 may be disposed on the first semiconductor layer 11, and may be formed to have a single or multi-quantum well structure. In an embodiment, a clad layer (not shown) doped with a conductive dopant may be formed at an upper portion and/or a lower portion of the active layer 12. For example, the clad layer may be formed as an AlGaN layer or an InAlGaN layer. In some embodiments, a material such as AlGaN and AlIn—GaN may be used to form the active layer 12, and in addition, various materials may form the active layer 12. The active layer 12 may be disposed between the first semiconductor layer 11 and the second semiconductor layer 13 to be described later.

In case that a voltage of a threshold voltage or more is applied to respective ends of the light emitting element LD, the light emitting element LD may emit light while electron-hole pairs are combined in the active layer 12. By controlling the light emission of the light emitting element LD by using this principle, the light emitting element LD may be used as a light source for various light emitting devices in addition to pixels of a display device.

The second semiconductor layer 13 may be disposed to on the active layer 12, and may include a semiconductor material of a type different from that of the first semiconductor layer 11. For example, the second semiconductor layer 13 may include at least one p-type semiconductor material. For example, the second semiconductor layer 13 may include at least one semiconductor material of InAlGaN, GaN, AlGaN, InGaN, AlN, and InN, and may include a p-type semiconductor material doped with a second conductive dopant such as Mg. However, the material included in the second semiconductor layer 13 is not limited thereto, and the second semiconductor layer 13 may be formed of various materials.

In some embodiments, the first length of the first semiconductor layer 11 may be longer than the second length of the second semiconductor layer 13.

In some embodiments, the light emitting element LD may further include an insulating film INF provided on a surface thereof. The insulating film INF may be formed on the surface of the light emitting element LD so as to surround at least an outer circumferential surface of the active layer 12, and may further surround an area of the first and second semiconductor layers 11 and 13.

In some embodiments, the insulating film INF may expose respective end portions of the light emitting element LD having different polarities. For example, the insulating film INF may not cover an end of each of the first and second semiconductor layers 11 and 13 disposed at both ends of the light emitting element LD in the length direction, for example, two flat surfaces (for example, upper and lower surfaces) of the circular cylinder, but may expose it. In some embodiments, the insulating film INF may expose both end portions of the light emitting element LD having different polarities and side portions of the semiconductor layers 11 and 13 adjacent to the end portions.

In some embodiments, the insulating film INF may include at least one insulating material of a barium sulfate (BaSO4), a lead carbonate (PbCO3), a titanium oxide (TiOx), a silicon oxide (SiOx), a zinc oxide (ZnOx), and an aluminum oxide (AlxOy), but is not necessarily limited thereto. For example, the insulating film INF may include at least one of a titanium dioxide (TiO2), a silicon dioxide (SiO2), a zinc oxide (ZnO), and an aluminum oxide (Al2O3).

In embodiments, the light emitting element LD may further include an additional component in addition to the first semiconductor layer 11, the active layer 12, the second semiconductor layer 13 and/or the insulating film INF. For example, the light emitting element LD may additionally include one or more of a phosphor layer, an active layer, a semiconductor layer, and/or an electrode layer disposed on an end side of the first semiconductor layer 11, the active layer 12, and/or the second semiconductor layer 13.

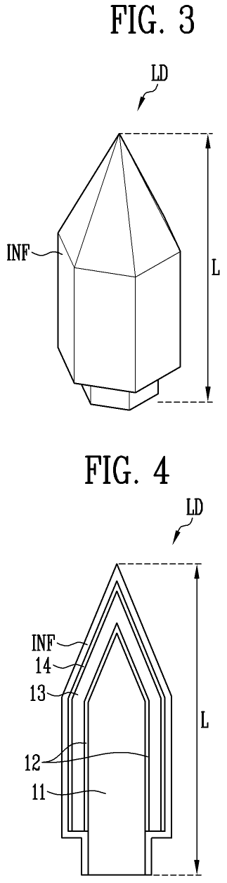

FIG. 3 and FIG. 4 illustrate a schematic perspective view and a schematic cross-sectional view of a light emitting element according to another embodiment.

Referring to FIG. 3 and FIG. 4, the light emitting element LD according to an embodiment, a first semiconductor layer 11 and a second semiconductor layer 13, and an active layer 12 interposed between the first and second semiconductor layers 11 and 13. In some embodiments, the first semiconductor layer 11 may be disposed in a central area of the light emitting element LD, and the active layer 12 may be disposed on the surface of the first semiconductor layer 11 to surround at least an area of the first semiconductor layer 11. The second semiconductor layer 13 may be disposed on a surface of the active layer 12 to surround at least an area of the active layer 12.

The light emitting element LD may further include an electrode layer 14 and/or an insulating film INF, surrounding at least an area of the second semiconductor layer 13. For example, the light emitting element LD may include the electrode layer 14 disposed on a surface of the second semiconductor layer 13 so as to surround an area of the second semiconductor layer 13, and the insulating film INF disposed on a surface of the electrode layer 14 so as to surround at least an area of the electrode layer 14. For example, the light emitting element LD according to an above-described embodiment may be implemented to have a core-shell structure including the first semiconductor layer 11, the active layer 12, the second semiconductor layer 13, the electrode layer 14, and the insulating film INF sequentially disposed from a center to an outer side, and the electrode layer 14 and/or insulating film INF may be omitted in some embodiments.

In an embodiment, the light emitting element LD may be provided in a polygonal horn shape extending along a direction. For example, at least an area of the light emitting element LD may have a hexagonal horn shape. However, the shape of the light emitting element LD is not limited thereto, and may be variously changed.

When an extending direction of the light emitting element LD is referred to as a length L direction, the light emitting element LD may be provided with an end portion and another end portion along the length L direction. In some embodiments, one of the first and second semiconductor layers 11 and 13 may be disposed at an end portion of the light emitting element LD, and the other of the first and second semiconductor layers 11 and 13 may be disposed at another end portion of the light emitting element LD.

In an embodiment, the light emitting element LD may be a polygonal columnar shape, for example, a micro-light emitting diode having a core-shell structure made of a hexagonal horn shape with both end portions protruding. For example, the light emitting element LD may have a size as small as a nanometer scale to a micrometer scale, for example, a width and/or a length L of a nanometer scale or micrometer scale range. However, the size and/or shape of the light emitting element LD may be variously changed according to design conditions of various devices using the light emitting element LD as a light source, for example, a display device.

In an embodiment, both end portions of the first semiconductor layer 11 along the length L direction of the light emitting element LD may have a protruding shape. The protruding shapes of both end portions of the first semiconductor layer 11 may be different from each other. For example, an end portion disposed at an upper side of both end portions of the first semiconductor layer 11 may have a horn shape contacting one vertex as a width thereof narrows toward an upper portion. Another end portion disposed at a lower side of both end portions of the first semiconductor layer 11 may have a polygonal column shape having a constant width, but is not limited thereto. For example, in another embodiment, the first semiconductor layer 11 may have a cross section of a polygonal shape or a step shape, which gradually decreases in width as it goes downward. The shapes of both end portions of the first semiconductor layer 11 may be variously changed according to embodiments, and thus, are not limited to an above-described embodiment.

In some embodiments, the first semiconductor layer 11 may be positioned at a core of the light emitting element LD, that is, at a center (or central area). The light emitting element LD may be provided to have a shape corresponding to a shape of the first semiconductor layer 11. For example, in case that the first semiconductor layer 11 has a hexagonal horn shape, the light emitting element LD may have a hexagonal horn shape.

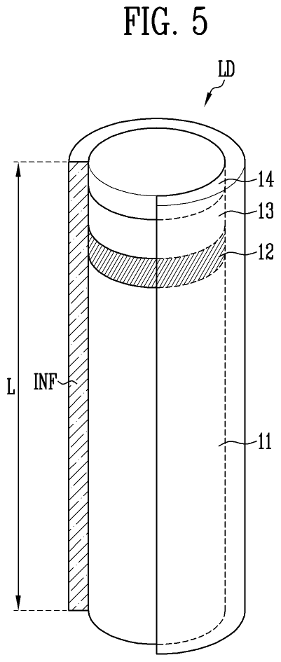

FIG. 5 illustrates a schematic perspective view of a light emitting element according to another embodiment. In FIG. 5, a portion of the insulating film INF is omitted for convenience of description.

Referring to FIG. 5, the light emitting element LD may further include an electrode layer 14 disposed on the second semiconductor layer 13. The electrode layer 14 may be an ohmic contact electrode electrically connected to the second semiconductor layer 13, but is not necessarily limited thereto. In some embodiments, the electrode layer 14 may be a Schottky contact electrode. The electrode layer 14 may include a metal or a metal oxide, and for example, Cr, Ti, Al, Au, Ni, ITO, IZO, ZnO, IGZO, ITZO, and an oxide thereof or an alloy thereof, and may be used alone or in combination. The electrode layer 14 may be substantially transparent or translucent. Accordingly, light generated by the active layer 12 of the light emitting element LD may pass through the electrode layer 14 to be emitted to the outside of the light emitting element LD.

Although not separately illustrated, in another embodiment, the light emitting element LD may further include an electrode layer disposed on the first semiconductor layer 11.

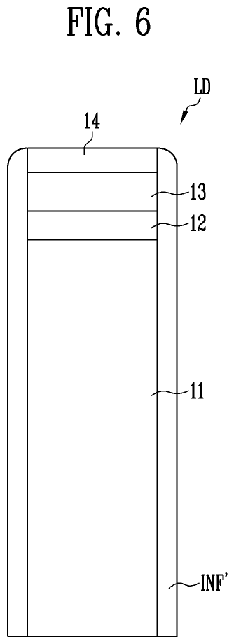

FIG. 6 illustrates a schematic cross-sectional view of a light emitting element according to another embodiment.

Referring to FIG. 6, an insulating film INF′ may have a curved shape in a corner area adjacent to the electrode layer 14. In some embodiments, the curved shape may be formed by etching in the manufacturing process of the light emitting element LD.

Although not separately shown, even in a light emitting element of another embodiment having the structure further including the electrode layer disposed on the first semiconductor layer 11, the insulating film INF′ may have a curved shape in an area adjacent to the electrode layer.

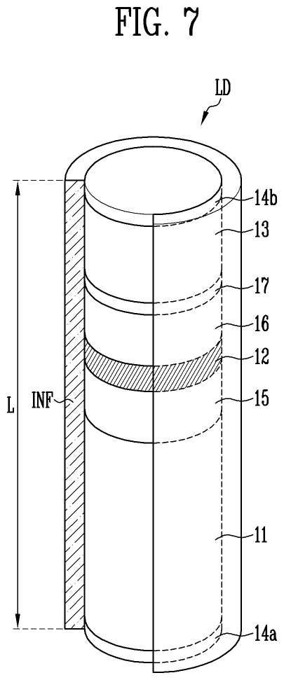

FIG. 7 illustrates a schematic perspective view of a light emitting element according to another embodiment. In FIG. 7, a portion of the insulating film INF is omitted for convenience of description.

Referring to FIG. 7, the light emitting element LD according to an embodiment may include a third semiconductor layer 15 disposed between the first semiconductor layer 11 and the active layer 12, and a fourth semiconductor layer 16 and a fifth semiconductor layer 17 disposed between the active layer 12 and the second semiconductor layer 13. The light emitting element LD of FIG. 7 may be different from that of an embodiment of FIG. 1 at least in that multiple semiconductor layers 15, 16, and 17 and electrode layers 14a and 14b are further disposed, and the active layer 12 contains other elements. Since the disposition and structure of the insulating film INF may be substantially the same as that of FIG. 1, the duplicate content will be omitted and the differences will be described below.

In the light emitting element LD of FIG. 1, the active layer 12 may include nitrogen (N) to emit blue light or green light. On the other hand, in the light emitting element LD of FIG. 7, the active layer 12 and other semiconductor layers may be a semiconductor including at least phosphorus (P), respectively. For example, the light emitting element LD according to an embodiment may emit red light. Specifically, in the light emitting element LD according to an embodiment of FIG. 7, the first semiconductor layer 11 may be an n-type semiconductor layer, and may be one or more of InAlGaP, GaP, AlGaP, InGaP, AlP, and InP doped with n-type. The first semiconductor layer 11 may be doped with an n-type dopant, and for example, the n-type dopant may be Si, Ge, Sn, and/or the like. In an embodiment, the first semiconductor layer 11 may be n-AlGaInP doped with n-type Si. A length of the first semiconductor layer 11 may be about 1.5 um to about 5 um, but is not necessarily limited thereto.

The second semiconductor layer 13 may be a p-type semiconductor layer, and may be one or more of InAlGaP, GaP, AlGaNP, InGaP, AlP, and InP doped with p-type. The second semiconductor layer 13 may be doped with a p-type dopant, and for example, the p-type dopant may be Mg, Zn, Ca, Se, Ba, and/or the like. In an embodiment, the second semiconductor layer 13 may be p-GaP doped with p-type Mg. A length of the second semiconductor layer 13 may be about 0.08 um to about 0.25 um, but is not necessarily limited thereto.

The active layer 12 may be disposed between the first semiconductor layer 11 and the second semiconductor layer 13. As in the active layer 12 of FIG. 1, the active layer 12 of FIG. 7 may also emit light of a specific wavelength band by including a material having a single or multiple quantum well structure. For example, in case that the active layer 12 emits light in a red wavelength band, the active layer 12 may include a material such as AlGaP or AlInGaP. Particularly, in case that the active layer 12 has a structure in which a quantum layer and a well layer are alternately stacked in a multi-quantum well structure, the quantum layer may include an inorganic material such as AlGaP or AlInGaP, and the well layer may include a material such as GaP or AlInP. In some embodiments, the active layer 12 may include AlGaInP as a quantum layer and AlInP as a well layer to emit red light.

The light emitting element LD of FIG. 7 may include a clad layer disposed adjacent to the active layer 12. As shown in the drawing, the third semiconductor layer 15 and the fourth semiconductor layer 16 disposed between the first semiconductor layer 11 and the second semiconductor layer 13 above and below the active layer 12 may be clad layers.

The third semiconductor layer 15 may be disposed between the first semiconductor layer 11 and the active layer 12. The third semiconductor layer 15 may be an n-type semiconductor like the first semiconductor layer 11, the first semiconductor layer 11 may be n-AlGaInP, and the third semiconductor layer 15 may be n-AlInP, but are not limited thereto.

The fourth semiconductor layer 16 may be disposed between the active layer 12 and the second semiconductor layer 13. The fourth semiconductor layer 16 may be an n-type semiconductor like the second semiconductor layer 13, the second semiconductor layer 13 may be p-GaP, and the fourth semiconductor layer 16 may be p-AlInP.

The fifth semiconductor layer 17 may be disposed between the fourth semiconductor layer 16 and the second semiconductor layer 13. The fifth semiconductor layer 17 may be a p-type doped semiconductor like the second semiconductor layer 13 and the fourth semiconductor layer 16. In some embodiments, the fifth semiconductor layer 17 may function to reduce a difference in lattice constant between the fourth semiconductor layer 16 and the second semiconductor layer 13. For example, the fifth semiconductor layer 17 may be a tensile strain barrier reducing (TSBR) layer. For example, the fifth semiconductor layer 17 may include p-GaInP, p-AlInP, and/or p-AlGaInP, but is not limited thereto. Lengths of the third semiconductor layer 15, the fourth semiconductor layer 16, and the fifth semiconductor layer 17 may be about 0.08 um to about 0.25 um, but are not limited thereto.

The first electrode layer 14a and the second electrode layer 14b may be disposed on the first semiconductor layer 11 and the second semiconductor layer 13, respectively. The first electrode layer 14a may be disposed on a lower surface of the first semiconductor layer 11, and the second electrode layer 14b may be disposed on an upper surface of the second semiconductor layer 13. However, the disclosure is not limited thereto, and at least one of the first electrode layer 14a and the second electrode layer 14b may be omitted. For example, in the light emitting element LD, the first electrode layer 14a is not disposed on the lower surface of the first semiconductor layer 11, and only the second electrode layer 14b may be disposed on the upper surface of the second semiconductor layer 13. The first electrode layer 14a and the second electrode layer 14b may each include at least one of the materials illustrated in the electrode layer 14 of FIG. 5.

The following embodiments will be described as an example to which the light emitting element LD shown in FIG. 1 and FIG. 2 is applied, but a person skilled in the art may apply various types of light emitting elements including the light emitting element LD shown in FIG. 3 to FIG. 7 to embodiments.

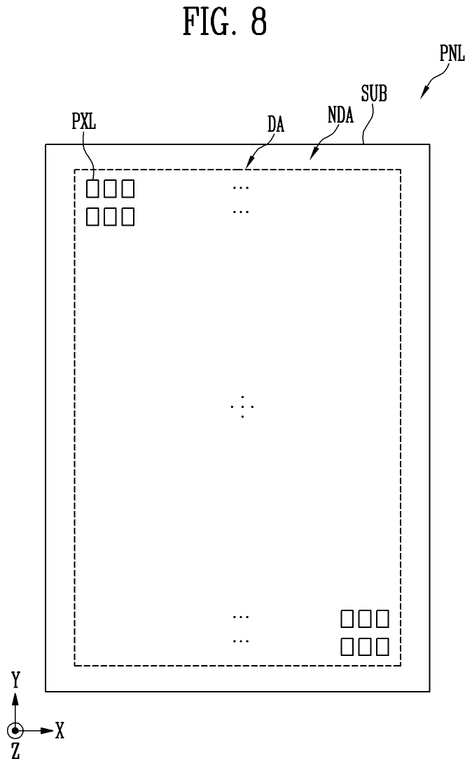

FIG. 8 illustrates a schematic plan view of a display device according to an embodiment. FIG. 8 illustrates a display device, which is an example of a device that may use an above-described light emitting element LD as a light source, particularly, a display panel PNL provided in the display device. Referring to FIG. 8, the display panel PNL may include a substrate SUB and multiple pixels PXL defined on the substrate SUB. Specifically, the display panel PNL and the substrate SUB may include a display area DA in which an image is displayed and a non-display area NDA excluding the display area DA.

In some embodiments, the display area DA may be disposed in a central area of the display panel PNL, and the non-display area NDA may be disposed along an edge of the display panel PNL so as to surround the display area DA. However, the positions of the display area DA and the non-display area NDA are not limited thereto, and they may be changed.

The substrate SUB may configure a base member of the display panel PNL. For example, the substrate SUB may configure a base member of a lower panel (for example, a lower panel of the display panel PNL).

In some embodiments, the substrate SUB may be a rigid substrate or a flexible substrate, and its material or physical properties are not particularly limited. For example, the substrate SUB may be a rigid substrate made of glass or tempered glass, or a flexible substrate made of a thin film made of plastic or metal. The substrate SUB may be a transparent substrate, but is not limited thereto. For example, the substrate SUB may be a translucent substrate, an opaque substrate, or a reflective substrate.

An area on the substrate SUB may be defined as the display area DA in which the pixels PXL are disposed, and the remaining area may be defined as the non-display area NDA. For example, the substrate SUB may include the display area DA including multiple pixel areas in which the pixels PXL are formed, and the non-display area NDA disposed outside the display area DA. In the non-display area NDA, various wires connected to the pixels PXL of the display area DA and/or internal circuit parts may be disposed.

The pixels PXL may include at least one light emitting element LD driven by corresponding scan and data signals, for example, at least one rod-shaped light emitting diode according to one of the embodiments of FIG. 1 to FIG. 7. For example, each of the pixels PXL may include multiple rod-shaped light emitting diodes having a size as small as a nanometer scale to a micrometer scale and connected to each other in parallel or in series. Multiple rod-shaped light emitting diodes may configure a light source of the pixels PXL.

Although FIG. 8 illustrates an embodiment in which the pixels PXL are arranged in a stripe form in the display area DA, the disclosure is not necessarily limited thereto. For example, the pixels PXL may be arranged in various pixel arrangement types.

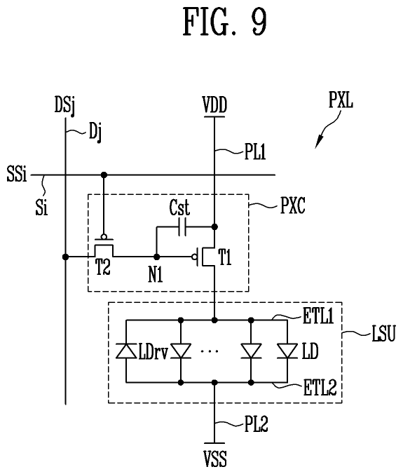

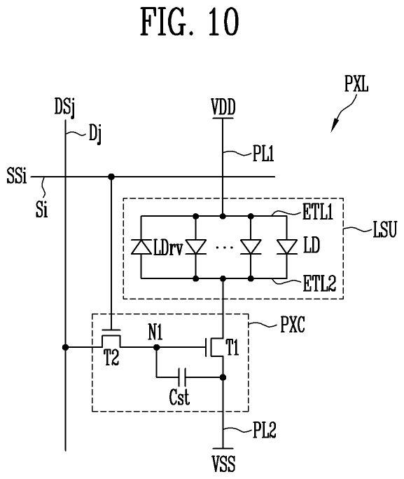

FIG. 9 to FIG. 13 illustrate schematic circuit diagrams of a pixel according to an embodiment.

FIG. 9 to FIG. 13 illustrate different embodiments of a pixel PXL that may be applied to an active display device. However, the types of the pixel PXL and the display device to which embodiments of the disclosure may be applied are not limited thereto.

First, referring to FIG. 9, the pixel PXL may include a light source unit LSU for generating light with luminance corresponding to a data signal. The pixel PXL may further selectively include a pixel circuit PXC for driving the light source unit LSU.

The light source unit LSU may include at least one light emitting element LD connected between a first power source VDD and a second power source VSS, for example, multiple light emitting elements LD. For example, the light source unit LSU may include a first electrode ETL1 (also referred to as a “first pixel electrode” or “first alignment electrode”) connected to the first power source VDD via the pixel circuit PXC and a first power line PL1, a second electrode ETL2 (also referred to as a “second pixel electrode” or “second alignment electrode”) connected to the second power source VSS through a second power line PL2, and multiple light emitting elements LD connected in parallel in the same direction between the first and second electrodes ETL1 and ETL2. In embodiments, the first electrode ETL1 may be an anode electrode, and the second electrode ETL2 may be a cathode electrode.

Each of the light emitting elements LD may include a first end portion (for example, a P-type end portion) connected to the first power source VDD through the first electrode ETL1 and/or the pixel circuit PXC, and a second end portion (for example, an N-type end portion) connected to the second power source VSS through the second electrode ETL2. For example, the light emitting elements LD may be connected in parallel in a forward direction between the first and second electrodes ETL1 and ETL2. Respective light emitting elements LD connected in the forward direction between the first power source VDD and the second power source VSS configure respective effective light sources, and these effective light sources may be combined to configure the light source unit LSU of the pixel PXL.

In some embodiments, the first and second power sources VDD and VSS may have different potentials so that the light emitting elements LD may emit light. For example, the first power source VDD may be set as a high potential power source, and the second power source VSS may be set as a low potential power source. A potential difference between the first and second power source sources VDD and VSS may be set to be equal to or higher than a threshold voltage of the light emitting elements LD during at least a light emitting period of the pixel PXL.

In some embodiments, end portions (for example, P-type end portions) of the light emitting elements LD configuring each light source unit LSU may be commonly connected to the pixel circuit PXC through an electrode (for example, the first pixel electrode ETL1 of each pixel PXL) of the light source unit LSU, and may be connected to the first power source VDD through the pixel circuit PXC and the first power line PL1. Other end portions (for example, N-type end portions) of the light emitting elements LD may be commonly connected to the second power source VSS through another electrode (for example, the second electrode ETL2 of each pixel PXL) of the light source unit LSU and the second power wire PL2.

The light emitting elements LD may emit light with luminance corresponding to a driving current supplied through the corresponding pixel circuit PXC. For example, during each frame period, the pixel circuit PXC may supply a driving current corresponding to a grayscale value to be displayed in the corresponding frame to the light source unit LSU. The driving current supplied to the light source unit LSU may be divided to flow in the light emitting elements LD that are connected in a forward direction. Therefore, while each light emitting element LD emits light with a luminance corresponding to the current flowing therein, the light source unit LSU may emit light having a luminance corresponding to the driving current.

In an embodiment, the light source unit LSU may further include at least one ineffective light source in addition to the light emitting elements LD configuring each effective light source. For example, at least one reverse direction light emitting element LDrv may be further connected between the first and second electrodes ETL1 and ETL2.

Each reverse light emitting element LDrv may be connected in parallel between the first and second electrodes ETL1 and ETL2 together with the light emitting elements LD forming the effective light sources, but may be connected between the first and second electrodes ETL1 and ETL2 in the opposite direction with respect to the light emitting elements LD. For example, an N-type end portion of the reverse direction light emitting element LDrv may be connected to the first power source VDD via the first electrode ETL1 and pixel circuit PXC, and a P-type end portion of the reverse direction light emitting element LDrv may be connected to the second power source VSS via the second electrode ETL2. The reverse direction light emitting element LDrv may maintain a deactivated state even if a predetermined or given driving voltage (for example, driving voltage of forward direction) is applied between the first and second electrodes ETL1 and ETL2, and accordingly, the reverse direction light emitting element LDrv may maintain a substantially non-light emitting state.

In some embodiments, at least one pixel PXL may further include at least one ineffective light source (not shown) that is not fully connected between the first and second electrodes ETL1 and ETL2. For example, at least one pixel PXL may further include at least one ineffective light emitting element that is positioned within the light source unit LSU, and of which respective end portions are not fully connected to the first and second electrodes ETL1 and ETL2.

The pixel circuit PXC may be connected between the first power source VDD and the first electrode ETL1. The pixel circuit PXC may be connected to a scan line Si and a data line Dj of the pixel PXL. For example, in case that the pixel PXL is disposed in an i-th horizontal line (row) (I is a natural number) and a j-th vertical line (column) (j is a natural number) of the display area DA, the pixel circuit PXC of the pixel PXL may be connected to an i-th scan line Si and a j-th data line Dj of the display area DA.

In some embodiments, the pixel circuit PXC may include multiple transistors and at least one capacitor. For example, the pixel circuit PXC may include a first transistor T1, a second transistor T2, and a storage capacitor Cst.

The first transistor T1 may be connected between the first power source VDD and the light source unit LSU. For example, a first electrode (for example, a source electrode) of the first transistor T1 may be connected to the first power source VDD, and a second electrode (for example, a drain electrode) of the first transistor T1 may be connected to the first electrode ETL1. A gate electrode of the first transistor T1 may be connected to a first node N1. The first transistor T1 may control a driving current supplied to the light source unit LSU in response to a voltage of the first node N1. For example, the first transistor T1 may be a driving transistor that controls a driving current of the pixel PXL.

The second transistor T2 may be connected between the data line Dj and the first node N1. For example, a first electrode (for example, a source electrode) of the second transistor T2 may be connected to the data line Dj, and a second electrode (for example, a drain electrode) of the second transistor T2 may be connected to the first node N1. A gate electrode of the second transistor T2 may be connected to the scan line Si. In case that a scan signal SSi of a gate-on voltage (for example, a low level voltage) is supplied from the scan line Si, the second transistor T2 may be turned on to electrically connect the data line Dj and the first node N1.

For each frame period, a data signal DSj of the corresponding frame may be supplied to the data line Dj, and the data signal DSj may be transmitted to the first node N1 through the turned-on second transistor T2 during a period in which the scan signal SSi of the gate-on voltage is supplied. For example, the second transistor T2 may be a switching transistor for transmitting each data signal DSj to the inside of the pixel PXL.

An electrode of the storage capacitor Cst may be connected to the first power source VDD, and another electrode thereof may be connected to the first node N1. The storage capacitor Cst may be charged with a voltage corresponding to the data signal DSj supplied to the first node N1 during each frame period.

FIG. 9 illustrates the transistors included in the pixel circuit PXC, for example, the first and second transistors T1 and T2 as P-type transistors, but the disclosure is not limited thereto. For example, at least one of the first and second transistors T1 and T2 may be changed to an N-type transistor.

For example, as shown in FIG. 10, each of the first and second transistors T1 and T2 may be an N-type transistor. A gate-on voltage of the scan signal SSi for writing the data signal DSj supplied to the data line Dj for each frame period to the pixel PXL may be a high level voltage (also referred to as a “gate-high voltage”). Similarly, a voltage of the data signal DSj for turning on the first transistor T1 may be a voltage of a level opposite to that in an embodiment of FIG. 9. For example, in an embodiment of FIG. 9, the data signal DSj of a lower voltage may be supplied as a grayscale value to be expressed increases, whereas in an embodiment of FIG. 10, the data signal DSj of a higher voltage may be supplied as a grayscale value to be expressed increases. In another embodiment, the first and second transistors T1 and T2 may be transistors of different conductive types. For example, one of the first and second transistors T1 and T2 may be a P-type transistor, and the other thereof may be an N-type transistor.

In an embodiment, interconnection positions of the pixel circuit PXC and the light source unit LSU may be changed. For example, as shown in FIG. 10, in case that both the first and second transistors T1 and T2 included in the pixel circuit PXC are N-type transistors, the pixel circuit PXC may be connected between the light source unit LSU and the second power source VSS, the storage capacitor Cst may be connected between the first node N1 and the second power source VSS. However, the disclosure is not limited thereto. For example, in another embodiment, even if the pixel circuit PXC is configured of N-type transistors, the pixel circuit PXC may be connected between the first power source VDD and the light source unit LSU, and/or the storage capacitor Cst may be connected between the first power source VDD and the first node N1.

The configuration and operation of the pixel PXL shown in FIG. 10 may be substantially similar to those of the pixel PXL of FIG. 9, except that connection positions of some circuit elements and voltage levels of control signals (for example, the scan signal SSi and the data signal DSj) may be changed in case that the type of the first and second transistors T1 and T2 is changed. Therefore, a detailed description of the pixel PXL of FIG. 10 will be omitted.

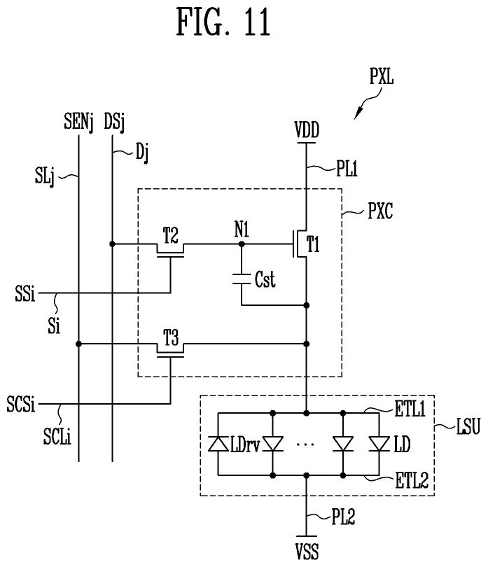

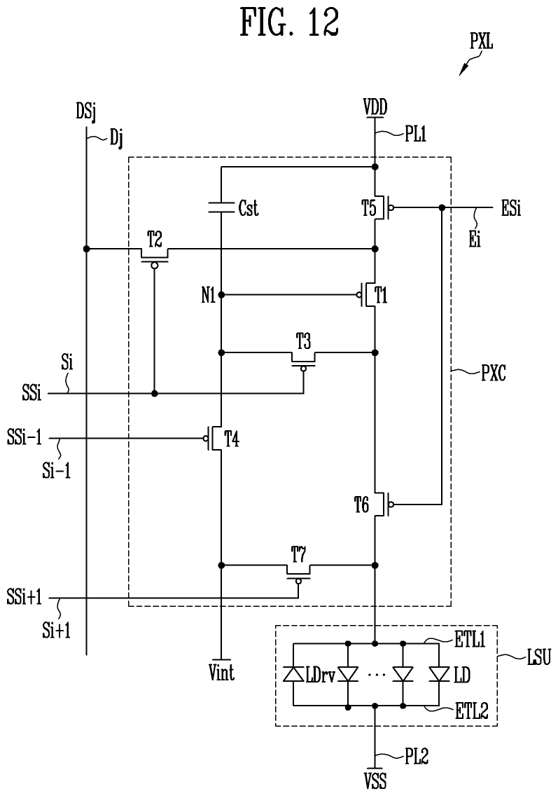

The structure of the pixel circuit PXC is not limited to an embodiment illustrated in FIG. 9 and FIG. 10. For example, the pixel circuit PXC may be configured as in an embodiment illustrated in FIG. 11 or FIG. 12. That is, the pixel circuit PXC may be configured as a pixel circuit having various structures and/or driving methods.

Referring to FIG. 11, the pixel circuit PXC may be further connected to a sensing control line SCLi and a sensing line SLj. For example, the pixel circuit PXC of the pixel PXL disposed at an i-th horizontal line and a j-th vertical line of the display area DA may be connected to an i-th sensing control line SCLi and a j-th sensing line SLj of the display area DA. The pixel circuit PXC may further include a third transistor T3. In another embodiment, the sensing line SLj may be omitted, and the characteristics of the pixel PXL may also be detected by detecting a sensing signal SENj through the data line Dj of the corresponding pixel PXL (or adjacent pixel).

The third transistor T3 may be connected between the first transistor T1 and the sensing line SLj. For example, an electrode of the third transistor T3 may be connected to an electrode (for example, a source electrode) of the first transistor T1 connected to the first electrode ETL1, and another electrode thereof may be connected to the sensing line SLj. In case that the sensing line SLj is omitted, the another electrode of the third transistor T3 may also be connected to the data line Dj.

A gate electrode of the third transistor T3 may be connected to the sensing control line SCLi. In case that the sensing control line SCLi is omitted, the gate electrode of the third transistor T3 may be connected to the scan line Si. The third transistor T3 may be turned on by a sensing control signal SCSi of a gate-on voltage (for example, a high level voltage) supplied to the sensing control line SCLi during a predetermined or given sensing period to electrically connect the sensing line SLj and the first transistor T1.

In some embodiments, the sensing period may be a period for extracting characteristics (for example, a threshold voltage of the first transistor T1) of each of the pixels PXL disposed in the display area DA. During the sensing period, the first transistor T1 may be turned on by supplying a predetermined or given reference voltage at which the first transistor T1 may be turned on to the first node N1 through the data line Dj and the second transistor T2 and by connecting each pixel PXL to a current source or the like. By supplying the sensing control signal SCSi of a gate-on voltage to the third transistor T3 to turn on the third transistor T3, the first transistor T1 may be connected to the sensing line SLj. Thereafter, the sensing signal SENj may be obtained through the sensing line SLj, and the characteristics of each pixel PXL in addition to the threshold voltage of the first transistor T1 may be detected by using the sensing signal SENj. Information on the characteristics of each pixel PXL may be used to convert image data so that a characteristic difference between the pixels PXL disposed in the display area DA may be compensated.

FIG. 11 illustrates an embodiment in which the first, second, and third transistors T1, T2, and T3 are all N-type transistors, but the disclosure is not limited thereto. For example, at least one of the first, second, and third transistors T1, T2, and T3 may be changed to a P-type transistor. FIG. 11 illustrates an embodiment in which the light source unit LSU is connected between the pixel circuit PXC and the second power source VSS, but the disclosure is not limited thereto. For example, in another embodiment, the light source unit LSU may be connected between the first power source VDD and the pixel circuit PXC.

Referring to FIG. 12, the pixel circuit PXC may be further connected to at least one other scan line or control line in addition to the scan line Si of the corresponding horizontal line. For example, the pixel circuit PXC of the pixel PXL disposed in the i-th horizontal line of the display area DA may be further connected to an (i−1)-th scan line Si−1 and/or an (i+1)-th scan line Si+1. The pixel circuit PXC may be further connected to another power source in addition to the first and second power sources VDD and VSS. For example, the pixel circuit PXC may also be connected to an initialization power source Vint. In an embodiment, the pixel circuit PXC may include first to seventh transistors T1 to T7 and a storage capacitor Cst.

The first transistor T1 may be connected between the first power source VDD and the light source unit LSU. For example, an electrode (for example, a source electrode) of the first transistor T1 may be connected to the first power source VDD through the fifth transistor T5 and the first power line PL1, and another electrode (for example, a drain electrode) of the first transistor T1 may be connected to an electrode (for example, the first electrode ETL1) of the light source unit LSU via the sixth transistor T6. A gate electrode of the first transistor T1 may be connected to a first node N1. The first transistor T1 may control a driving current supplied to the light source unit LSU in response to a voltage of the first node N1.

The second transistor T2 may be connected between the data line Dj and an electrode (for example, the source electrode) of the first transistor T1. A gate electrode of the second transistor T2 may be connected to the corresponding scan line Si. In case that a scan signal SSi of a gate-on voltage is supplied from the scan line Si, the second transistor T2 may be turned on to electrically connect the data line Dj to an electrode of the first transistor T1. Therefore, in case that the second transistor T2 is turned on, the data signal DSj supplied from the data line Dj may be transmitted to the first transistor T1.

The third transistor T3 may be connected between another electrode (for example, the drain electrode) of the first transistor T1 and the first node N1. A gate electrode of the third transistor T3 may be connected to the corresponding scan line Si. In case that the scan signal SSi of the gate-on voltage is supplied from the scan line Si, the third transistor T3 may be turned on to connect the first transistor T1 in a form of a diode. Accordingly, during the period in which the scan signal SSi of the gate-on voltage is supplied, the first transistor T1 may be turned on in a diode-connected form, and accordingly, the data signal DSj from the data line Dj sequentially passes through the second transistor T2, the first transistor T1, and the third transistor T3 to be supplied to the first node N1. Accordingly, the storage capacitor Cst may be charged with a voltage corresponding to the data signal DSj and the threshold voltage of the first transistor T1.

The fourth transistor T4 may be connected between the first node N1 and the initialization power source Vint. A gate electrode of the fourth transistor T4 may be connected to a previous scan line, for example, an (i−1)-th scan line Si−1. In case that the scan signal SSi−1 of the gate-on voltage is supplied to the (i−1)-th scan line Si−1, the fourth transistor T4 may be turned on to transmit a voltage of the initialization power source Vint to the first node N1.

In some embodiments, the voltage of the initialization power source Vint may be equal to or less than the lowest voltage of the data signal DSj. Before the data signal DSj of the corresponding frame is supplied to each pixel PXL, the first node N1 is initialized to the voltage of the initialization power supply Vint by the scan signal SSi−1 of the gate-on voltage supplied to the (i−1)-th scan line Si−1. Accordingly, regardless of the voltage of the data signal DSj of the previous frame, the first transistor T1 may be diode-connected in the forward direction while the scan signal SSi of the gate-on voltage is supplied to the i-th scan line Si. Accordingly, the data signal DSj of the corresponding frame may be transmitted to the first node N1.

The fifth transistor T5 may be connected between the first power source VDD and the first transistor T1. A gate electrode of the fifth transistor T5 may be connected to the corresponding emission control line, for example, an i-th emission control line Ei. In case that an emission control signal ESi of a gate-off voltage (for example, a high level voltage) is supplied to the emission control line Ei, the fifth transistor T5 may be turned off, and may be turned on in other cases.

The sixth transistor T6 may be connected between the first transistor T1 and the light source unit LSU. A gate electrode of the sixth transistor T6 may be connected to the corresponding emission control line, for example, the i-th emission control line Ei. In case that an emission control signal ESi having the gate-off voltage is supplied to the emission control line Ei, the sixth transistor T6 may be turned off, and may be turned on in other cases.

The fifth and sixth transistors T5 and T6 may control a emission period of the pixel PXL. For example, in case that the fifth and sixth transistors T5 and T6 are turned on, a current path in which a driving current may flow from the first power source VDD to the second power source VSS through the fifth transistor T5, the first transistor T1, the sixth transistor T6, and the light source unit LSU in sequence, may be formed. In case that the fifth and/or sixth transistors T5 and T6 are turned off, the current path is blocked, and light emission of the pixel PXL may be prevented.

The seventh transistor T7 may be connected between an electrode of the light source unit LSU (for example, the first electrode ETL1) and the initialization power source Vint. A gate electrode of the seventh transistor T7 may be connected to a scan line for selecting the pixels PXL of a next horizontal line, for example, to an (i+1)-th scan line Si+1. In case that a scan signal SSi+1 of the gate-on voltage is supplied to the (i+1)-th scan line Si+1, the seventh transistor T7 may be turned on to supply the voltage of the initialization power source Vint to an electrode of the light source unit LSU (for example, the first pixel electrode ETL1). Accordingly, during each initialization period in which the voltage of the initialization power source Vint is transmitted to the light source unit LSU, the voltage of an electrode of the light source unit LSU may be initialized.

The control signal and/or the initialization power source Vint for controlling the operation of the seventh transistor T7 may be variously changed. For example, in another embodiment, the gate electrode of the seventh transistor T7 may also be connected to the scan line of the corresponding horizontal line, that is, the i-th scan line Si or the scan line of the previous horizontal line, for example, the (i−1)-th scan line Si−1. In case that the scan signal SSi or SSi−1 of the gate-on voltage is supplied to the i-th scan line Si or the (i−1)-th scan line Si−1, the seventh transistor T7 may be turned on to supply the voltage of the initialization power source Vint to an electrode of the light source unit LSU. Accordingly, during each frame period, the pixel PXL may emit light with a more uniform luminance in response to the data signal DSj. In some embodiments, the fourth transistor T4 and the seventh transistor T7 may be connected to respective initialization power sources having different potentials. For example, in some embodiments, multiple initialization power sources may be supplied to the pixel, and the first node N1 and the first electrode ETL1 may be initialized by initialization power sources having different potentials.

The storage capacitor Cst may be connected between the first power source VDD and the first node N1. The storage capacitor Cst may store the data signal DSj supplied to the first node N1 in each frame period and a voltage corresponding to the threshold voltage of the first transistor T1.

FIG. 12 illustrates the transistors included in the pixel circuit PXC, for example, the first to seventh transistors T1 to T7 as P-type transistors, but the disclosure is not limited thereto. For example, at least one of the first to seventh transistors T1 and T7 may be changed to an N-type transistor.

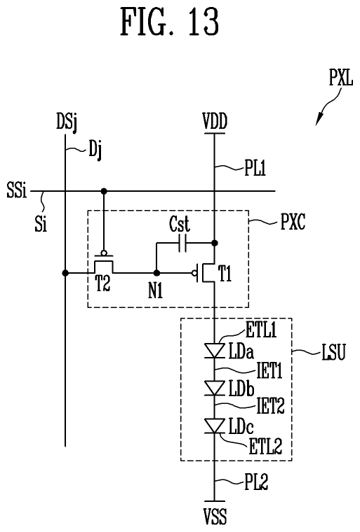

FIG. 9 to FIG. 12 illustrate embodiments in which effective light sources forming each light source unit LSU, that is, the light emitting elements LD are all connected in parallel, but the disclosure is not limited thereto. For example, in another embodiment of the disclosure, as shown in FIG. 13, the light source unit LSU of each pixel PXL may be configured to include at least two stages in series. In describing embodiments of FIG. 13, a detailed description of the configuration (for example, the pixel circuit PXC) that is similar to or the same as embodiments of FIG. 9 to FIG. 12 will be omitted.

Referring to FIG. 13, the light source unit LSU may include at least two light emitting elements connected in series to each other. For example, the light source unit LSU may include first to third light emitting elements LDa, LDb, and LDc connected in series in a forward direction between the first power source VDD and the second power source VSS. Each of the first, second, and third light emitting elements LDa, LDb, and LDc may configure an effective light source.

A first end portion (for example, P-type end portion) of the first light emitting element LDa may be connected to the first power source VDD via the first electrode ETL1 (for example, first pixel electrode) of the light source unit LSU. A second end portion (for example, N-type end portion) of the first light emitting element LDa may be connected to a first end portion (for example, P-type end portion) of the second light emitting element LDb through a first middle electrode IET1.

The first end portion (for example, P-type end portion) of the second light emitting element LDb may be connected to a second end portion of the first light emitting element LDa. The second end portion (for example, N-type end) of the second light emitting element LDb may be connected to a first end portion (for example, P-type end portion) of the third light emitting element LDc through a second middle electrode IET2.

The first end portion of the third light emitting element LDc (for example, P-type end portion) may be connected to the second end portion of the second light emitting element LDb. A second end portion of the third light emitting element LDc (for example, N-type end portion) may be connected to the second power supply VSS via the second electrode (for example, second pixel electrode ETL2) of the light source unit LSU. In the above-described manner, the first, second, and third light emitting elements LDa, LDb, and LDc may be sequentially connected in series between the first and second electrodes ETL1 and ETL2 of the light source unit LSU.

FIG. 13 illustrates an embodiment in which light emitting elements LD are connected in a three-stage series structure, but the disclosure is not limited thereto. For example, in another embodiment of the disclosure, two light emitting elements LD may be connected in a two-stage series structure, or four or more light emitting elements LD may be connected in a four-stage or more series structure.

Assuming that the same luminance is expressed using the light-emitting elements LD of the same condition (for example, the same size and/or number), in the light source unit LSU having a structure in which the light emitting elements LD are connected in series compared to the light source unit LSU having a structure in which the light emitting elements LD are connected in parallel, a voltage applied between the first and second electrodes ETL1 and ETL2 may increase, a driving current flowing through the light source unit LSU may decrease. Therefore, in case that the light source unit LSU of each pixel PXL is configured by applying the serial structure, a panel current flowing through the display panel PNL may be reduced.

Although not separately illustrated, in some embodiments, at least one serial stage may include multiple light emitting elements LD connected in parallel to each other. The light source unit LSU may be configured in a series/parallel mixed structure.

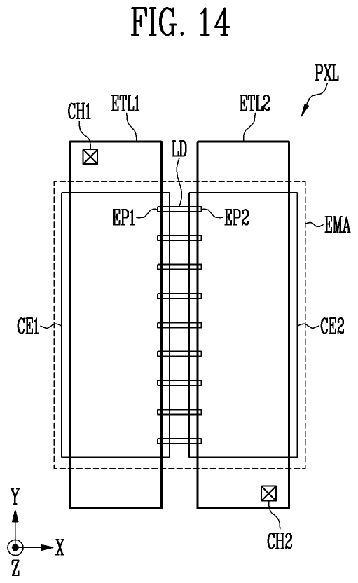

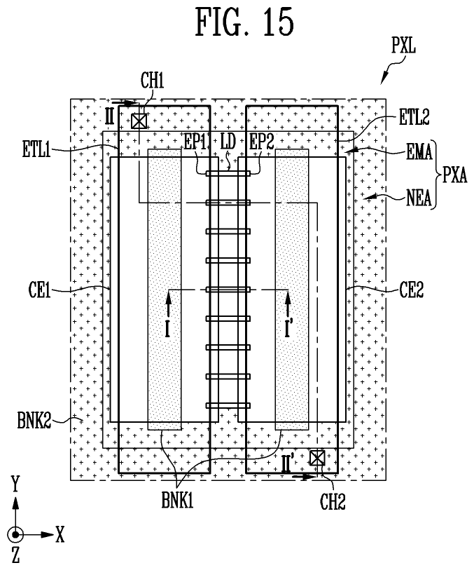

FIG. 14 and FIG. 15 illustrate schematic plan views of a pixel according to an embodiment.

In FIG. 14 and FIG. 15, a structure of the pixel PXL is illustrated based on the light source unit LSU of each pixel PXL. However, in some embodiments, each pixel PXL may selectively further include circuit elements (for example, multiple circuit elements configuring each pixel circuit PXC) connected to the light source unit LSU.

FIG. 14 and FIG. 15 illustrate an embodiment in which each light source unit LSU is connected to a predetermined or given power line (for example, the first and/or second power lines PL1 and PL2), a circuit element (for example, at least one circuit element configuring the pixel circuit PXC), and/or a signal line (for example, the scan line Si and/or the data line Dj), through first and second contact holes CH1 and CH2. However, the disclosure is not limited thereto. For example, in another embodiment, at least one of the first and second electrodes ETL1 and ETL2 of each pixel PXL may be directly connected to a predetermined or given power line and/or signal line without passing through a contact hole and/or a middle line.

First, referring to FIG. 14, the pixel PXL may include the first electrode ETL1 and the second electrode ETL2 disposed in each light emitting area EMA, and at least one light-emitting element LD (for example, the light emitting elements LD connected between the first and second electrodes ETL1 and ETL2) disposed between the first and second electrodes ETL1 and ETL2. The pixel PXL may further include a first contact electrode CE1 and a second contact electrode CE2 for electrically connecting the light emitting element LD between the first and second electrodes ETL1 and ETL2.

The first electrode ETL1 and the second electrode ETL2 may be disposed in the light emitting area EMA of each pixel PXL. The light-emitting area EMA may be an area in which the light-emitting elements LD (in particular, effective light sources completely connected between the first and second electrodes ETL1 and ETL2) configuring the light source unit LSU of each pixel PXL are disposed. An area of predetermined or given electrodes connected to the light emitting elements LD (for example, the first and second electrodes ETL1 and ETL2 and/or the first and second contact electrodes CE1 and CE2) or of above-mentioned electrodes may be disposed in the light emitting area EMA.

The first and second electrodes ETL1, and ETL2 may be disposed apart from each other. For example, the first and second electrodes ETL1 and ETL2 may be spaced apart side by side by a predetermined or given interval along a first direction (X-axis direction) in each light emitting area EMA.

On the other hand, before the process of forming the pixel PXL, particularly before the alignment of the light emitting elements LD is completed, the first electrodes ETL1 of the pixels PXL disposed in the display area DA may be connected to each other, and the second electrodes ETL2 of the pixels PXL may be connected to each other. The first and second electrodes ETL1 and ETL2 may receive a first alignment signal (or first alignment voltage) and a second alignment signal (or second alignment voltage), respectively, in an alignment step of the light emitting elements LD. For example, one of the first and second electrodes ETL1 and ETL2 may be supplied with an AC-type alignment signal, and the other of the first and second electrodes ETL1 and ETL2 may be supplied with an alignment voltage (for example, a ground voltage) having a constant voltage level. For example, a predetermined or given alignment signal may be applied to the first and second electrodes ETL1 and ETL2 in the alignment step of the light emitting elements LD. Accordingly, an electric field may be formed between the first and second electrodes ETL1 and ETL2. The light emitting elements LD provided in the light emitting area EMA of the pixel PXL may be self-aligned between the first and second electrodes ETL1 and ETL2 by the electric field. After the alignment of the light emitting elements LD is completed, by disconnecting the at least first electrodes ETL1 between the pixels PXL, the pixels PXL may be formed in a form capable of being individually driven.

The first and second electrodes ETL1 and ETL2 may have various shapes. For example, as shown in FIG. 14 and FIG. 15, each of the first and second electrodes ETL1 and ETL2 may have a bar-like shape extending along a direction. For example, each of the first and second electrodes ETL1 and ETL2 may have a bar shape extending along a second direction (Y-axis direction) crossing (for example, orthogonal to) the first direction (X-axis direction).

Although FIG. 14 and FIG. 15 illustrate the case in which one first electrode ETL1 and one second electrode ETL2 are disposed in each light emitting area EMA, the number and disposition of the first and second electrodes ETL1 and ETL2 disposed in the light emitting area EMA of the pixel PXL may be variously changed. For example, in another embodiment, multiple first electrodes ETL1 and/or second electrodes ETL2 may be disposed in the light emitting area EMA of each pixel PXL.

In case that the multiple first electrodes ETL1 are disposed in one pixel PXL, the first electrodes ETL1 may be integrally or non-integrally connected to each other. For example, the first electrodes ETL1 may be integrally connected, or may be connected to each other by a bridge pattern positioned on a different layer (for example, a circuit layer on which the pixel circuit PXC is disposed) from the first electrodes. Similarly, in case that multiple second electrodes ETL2 are disposed in one pixel PXL, the second electrodes ETL2 may be integrally or non-integrally connected to each other. For example, the second electrodes ETL2 may be integrally connected to each other, or may be connected to each other by a bridge pattern positioned on a different layer from the second electrodes. For example, the shape, number, arrangement direction, and/or mutual disposed relationship of the first and second electrodes ETL1 and ETL2 disposed in each pixel PXL may be variously changed.

The first electrode ETL1 may be electrically connected to a predetermined or given circuit element (for example, at least one transistor configuring the pixel circuit PXC), a power line (for example, the first power line PL1), and/or a signal line (for example, the scan line Si, the data line Dj, or a predetermined or given control line), through the first contact hole CH1. However, the disclosure is not limited thereto. For example, in another embodiment, the first electrode ETL1 may be directly connected to a predetermined or given power wire or signal wire.

In an embodiment, the first electrode ETL1 may be electrically connected to a predetermined or given circuit element disposed thereunder through the first contact hole CH1, and to a first wire through the circuit element. The first wire may be a first power wire PL1 for supplying the first power source VDD, but is not limited thereto. For example, the first wire may be a signal wire to which a predetermined or given first driving signal (for example, a scan signal, a data signal, or a predetermined or given control signal) is supplied.

The second electrode ETL2 may be electrically connected to a predetermined or given circuit element (for example, at least one transistor configuring the pixel circuit PXC), a power line (wire) (for example, the second power line (wire) PL2), and/or a signal line (for example, the scan line Si, the data line Dj, or a predetermined or given control line), through the second contact hole CH2. However, the disclosure is not limited thereto. For example, in another embodiment, the second electrode ETL2 may be directly connected to a predetermined or given power wire or signal wire.

In an embodiment, the second electrode ETL2 may be electrically connected to the second wire disposed thereunder through the second contact hole CH2. The second wire may be a second power wire PL2 for supplying the second power source VSS, but is not limited thereto. For example, the second wire may be a signal wire to which a predetermined or given second driving signal (for example, a scan signal, a data signal, or a predetermined or given control signal) is supplied.

The light emitting elements LD may be disposed between the first electrode ETL1 and the second electrode ETL2. For example, each light emitting element LD may be disposed between the first electrode ETL1 and the second electrode ETL2 in the first direction (X-axis direction), and thus may be electrically connected between the first and second electrodes ETL1 and ETL2.

FIG. 14 and FIG. 15 illustrate that all of the light emitting elements LD are uniformly aligned in the first direction (X-axis direction), but the disclosure is not limited thereto. For example, at least one of the light emitting elements LD may be arranged in an oblique direction between the first and second electrodes ETL1 and ETL2.

In some embodiments, each light emitting element LD may be an ultra-small light emitting element using a material having an inorganic crystal structure, for example, having a size as small as nano-scale or micro-scale. For example, each light emitting element LD may be an ultra-small light emitting element having a size ranging from a nano scale to a micro scale, as shown in FIG. 1 to FIG. 7. However, the type and/or size of the light emitting element LD may be variously changed according to each light emitting device using the light emitting element LD as a light source, for example, according to a design condition of the pixel PXL.

The light emitting elements LD may emit light in the same color. For example, all of the light emitting elements LD may be sub-pixels that emit light in one of red, green, and blue. In order to configure a full-color pixel PXL, a color control layer and/or a color filter for converting a color of light emitted from the light emitting elements LD may be disposed at an upper portion of the light emitting elements LD. However, the disclosure is not necessarily limited thereto, and the light emitting elements LD may emit light in different colors.

Each light emitting element LD may include the first end portion EP1 disposed toward the first electrode ETL1 and the second end EP2 disposed toward the second electrode ETL2. The first end portion EP1 of each of the light emitting elements LD may be electrically connected to the first electrode ETL1, and the second end portion EP2 of each of the light emitting elements LD may be electrically connected to the second electrode ETL2. For example, the first end portion EP1 of each of the light emitting elements LD may be electrically connected to the first electrode ETL1 through the first contact electrode CE1, and the second end portion EP2 of each of the light emitting elements LD may be electrically connected to the second electrode ETL2 through the second contact electrode CE2. In another embodiment, the first end portion EP1 of each of the light emitting elements LD may directly contact the first electrode ETL1, and thus, may be connected to the first electrode ETL1. Similarly, the second end portion EP2 of each of the light emitting elements LD may directly contact the second electrode ETL2, and thus, may be connected to the second electrode ETL2. The first contact electrode CE1 and/or the second contact electrode CE2 may be selectively formed.

In some embodiments, the light emitting elements LD may be prepared in a form dispersed in a predetermined or given solution to be supplied to the light emitting area EMA of the pixel PXL through various methods including an inkjet method or a slit coating method. For example, the light emitting elements LD may be mixed with a volatile solvent, and may be supplied to the light emitting area EMA of each pixel PXL. In case that a predetermined or given alignment voltage (or alignment signal) is applied to the first and second electrodes ETL1 and ETL2 of the pixels PXL, an electric field may be formed between the first and second electrodes ETL1 and ETL2, and thus, the light emitting elements LD are aligned between the first and second electrodes ETL1 and ETL2. After the light emitting elements LD are aligned, the light emitting elements LD may be stably arranged between the first and second electrodes ETL1 and ETL2 by volatilizing the solvent or eliminating it in other ways.

In some embodiments, the first contact electrode CE1 and second contact electrode CE2 may be formed on both end portions of the light emitting elements LD, for example, the first and second end portions EP1 and EP2 thereof, respectively. Accordingly, the light emitting elements LD may be more stably connected between the first and second electrodes ETL1 and ETL2.

The first contact electrode CE1 may be disposed on the first electrode ETL1 and the first end portion EP1 of the light emitting element LD so as to overlap the first electrode ETL1 and the first end portion EP1 of the at least one light emitting element LD adjacent to the first electrode ETL1. The first contact electrode CE1 may electrically connect the first electrode ETL1 and the first end portions EP1 of the light emitting elements LD. The first contact electrode CE1 may stably fix the first end portions EP1 of the light emitting elements LD. On the other hand, in another embodiment, in case that the first contact electrode CE1 is not formed, the first end portions EP1 of the light emitting elements LD may be disposed to overlap the first electrode ETL1 adjacent thereto to be directly connected to the first electrode ETL1.

The second contact electrode CE2 may be disposed on the second electrode ETL2 and the second end portion EP2 of the light emitting element LD so as to overlap the second electrode ETL2 and the second end portion EP2 of the at least one light emitting element LD adjacent to the second electrode ETL2. The second contact electrode CE2 may electrically connect the second electrode ETL2 and the second end portions EP2 of the light emitting elements LD. The second contact electrode CE2 may stably fix the second end portions EP2 of the light emitting elements LD. On the other hand, in another embodiment, in case that the second contact electrode CE2 is not formed, the second end portions EP2 of the light emitting elements LD may be disposed to overlap the second electrode ETL2 adjacent thereto to be directly connected to the second electrode ETL2.

In the above-described embodiments, each light emitting element LD connected in a forward direction between the first and second electrodes ETL1 and ETL2 may form an effective light source of the corresponding pixel PXL. The effective light sources may be gathered to form the light source unit LSU of the corresponding pixel PXL.

For example, in case that the first power source VDD (or a predetermined or given first control signal in addition to a scan signal or a data signal) is applied to the first end portions EP1 of the light emitting elements LD via the first power line PL1, the first electrode ETL1, and/or the first contact electrode CE1 and in case that the second power source VSS (or a predetermined or given second control signal in addition to a scanning signal or a data signal) is applied to the second end portions EP2 of the light emitting elements LD via the second power line PL2, the second electrode ETL2, and/or the second contact electrode CE2, the light emitting elements LD connected in a forward direction between the first and second electrodes ETL1 and ETL2 emit light. Accordingly, light may be emitted from the pixel PXL.

Referring to FIG. 15, the pixel PXL may further include the first bank BNK1 overlapping the first and second electrodes ETL1 and ETL2, and the second bank BNK2 surrounding each light emitting area EMA.

The first bank BNK1 (also referred to as a “partition wall”) may be disposed under the first and second electrodes ETL1 and ETL2. For example, the first bank BNK1 may be disposed under the first and second electrodes ETL1 and ETL2 so as to respectively overlap areas of the first and second electrodes ETL1 and ETL2.

As the first bank BNK1 may be disposed under an area of each of the first and second electrodes ETL1 and ETL2, the first and second electrodes ETL1, and ETL2 may protrude in an upper direction (a third direction (Z-axis direction)) in an area in which the first bank BNK1 is formed. This first bank BNK1 may form a reflective bank (also referred to as a “reflective partition wall”) together with the first and second electrodes ETL1 and ETL2. For example, the first and second electrodes ETL1 and ETL2 and/or the first bank BNK1 may be formed of a reflective material, or at least one material layer having a reflective characteristic may be formed on the protruding sidewalls of the first and second electrodes ETL1 and ETL2 and/or the first bank BNK1. Accordingly, the light emitted from the first and second end portions EP1 and EP2 of the light emitting elements LD facing the first and second electrodes ETL1 and ETL2 may be induced to be more directed toward a front direction of the display panel PNL. As such, in case that an area of each of the first and second electrodes ETL1 and ETL2 is protruded in the upper direction by the first bank BNK1, a ratio of the light directed to the front direction (the third direction (Z-axis direction)) of the display panel PNL with respect to the light generated from the pixel PXL is increased, and thus, it may be possible to improve an optical efficiency of the pixel PXL.

In some embodiments, the first bank BNK1 may be omitted. The first and second electrodes ETL1 and ETL2 may be formed to be substantially flat, or may be formed to have a protrusion and depression surface. For example, by forming each of the first and second electrodes ETL1 and ETL2 to have a different thickness for each area to form a protrusion and depression surface, an area of the first and second electrodes ETL1 and ETL2 may protrude in the upper direction. Accordingly, the light emitted from the light emitting elements LD may be induced to be directed toward the front direction (the third direction (Z-axis direction)) of the display panel PNL.

The second bank BNK2 may be a structure defining the light emitting area EMA of each pixel PXL, and may be, for example, a pixel defining layer. For example, the second bank BNK2 may be disposed in a boundary area of each pixel area PXA in which the pixel PXL is provided and/or in an area between the pixels PXL adjacent thereto so as to surround the light emitting area EMA of each pixel PXL.

The second bank BNK2 may overlap an area (for example, both end portions) of the first and second electrodes ETL1 and ETL2 as shown in FIG. 15. The first and second contact holes CH1 and CH2 may be formed in the non-light emitting area NEA so as to overlap the second bank BNK2, or may be formed inside the light emitting area EMA so as to not overlap the second bank BNK2.

The second bank BNK2 may be configured to include at least one light-blocking and/or reflective material to prevent light leakage between adjacent pixels PXL. For example, the second bank BNK2 may include various types of black matrix materials (for example, at least one light blocking material), and/or a color filter material of a specific color. For example, the second bank BNK2 may be formed in a black opaque pattern to block light transmission. In an embodiment, a reflective layer (not shown) may be formed on a surface (for example, a side surface) of the second bank BNK2 to further increase a light efficiency of the pixel PXL.

The second bank BNK2 may function as a dam structure that defines each light emitting area EMA in which the light emitting elements LD should be supplied at the step of supplying the light emitting elements LD to each pixel PXL. For example, each light emitting area EMA is partitioned by the second bank BNK2, so that a desired type and/or amount of light emitting element ink may be supplied into the light emitting area EMA.

In an embodiment, the second bank BNK2 may be simultaneously formed in the same layer as the first banks BNK1 in the process of forming the first banks BNK1 of the pixels PXL. In another embodiment, the second bank BNK2 may be formed in the same or different layer as or from the first banks BNK1 through a separate process from the process of forming the first banks BNK1.

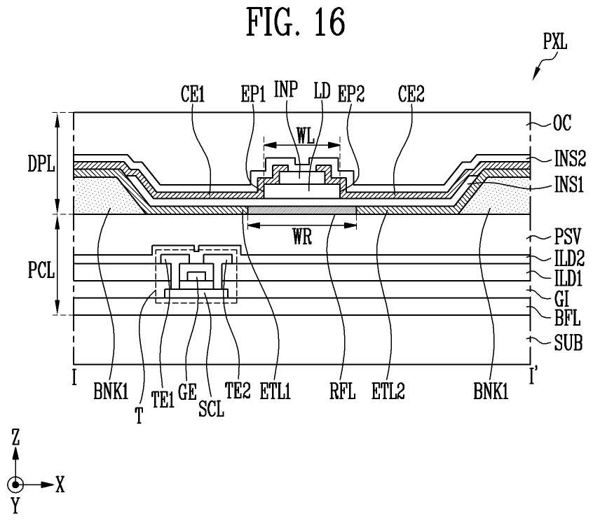

FIG. 16 to FIG. 18 illustrate schematic cross-sectional views of a pixel according to an embodiment.

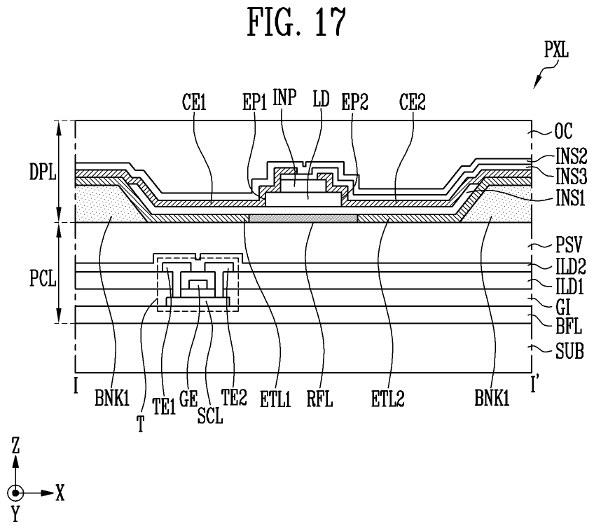

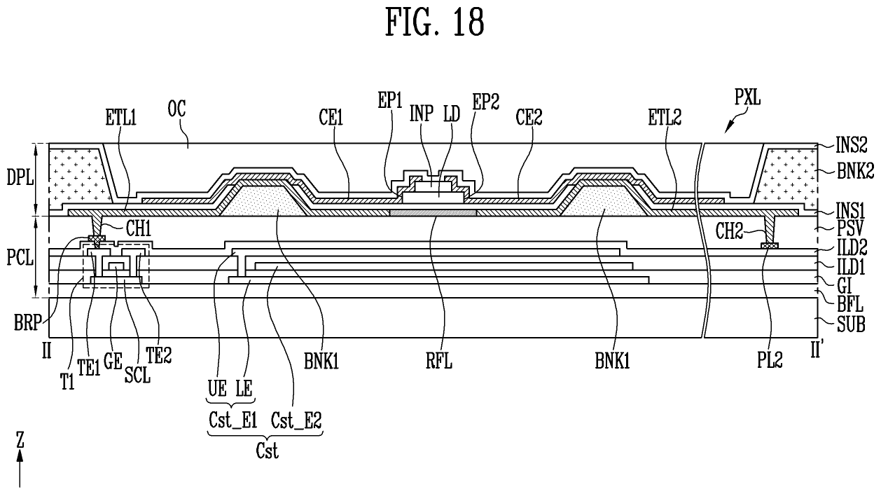

For example, FIG. 16 and FIG. 17 illustrate cross-sectional views taken along line I-″ of FIG. 15, and FIG. 18 illustrates a cross-sectional view taken along line II-″ of FIG. 15.

In order to illustrate various circuit elements included in the pixel circuit PXC, FIG. 16 and FIG. 17 illustrate an arbitrary transistor T among the circuit elements, and FIG. 18 illustrates a transistor (for example, the first transistor T1 of FIG. 6 and the like) connected to the first electrode ETL1 and a storage capacitor Cst among the circuit elements. Hereinafter, when it is not necessary to separately specify the first transistor T1, the first transistor T1 will also be comprehensively referred to as a “transistor T”.

Structures of the transistors T and the storage capacitor Cst and/or a position of each layer thereof are not limited to embodiments shown in FIG. 16 to FIG. 18, and may be variously changed according to embodiments. In the embodiment, the transistors T included in each pixel circuit PXC may have substantially the same or similar structure to each other, but are not limited thereto. For example, in another embodiment, at least one of the transistors T included in the pixel circuit PXC may have a different cross-sectional structure from the remaining other transistors T, and/or may be disposed at a different position in a cross-section view.

Referring to FIG. 16 to FIG. 18, the pixels PXL and the display device including the same according to an embodiment may include a circuit layer PCL and a light emitting element layer DPL disposed on the circuit layer PCL.

The circuit layer PCL may include the substrate SUB. The substrate SUB may be a rigid substrate or a flexible substrate, and its material or physical properties are not particularly limited. For example, the substrate SUB may be a rigid substrate made of glass or tempered glass, or a flexible substrate made of a thin film made of plastic or metal. The substrate SUB may be a transparent substrate, but is not necessarily limited thereto.

A buffer layer BFL may be disposed on the substrate SUB. The buffer layer BFL may function to smooth a surface of the substrate SUB and prevent penetration of moisture or external air. The buffer layer BFL may be an inorganic film configured of a single layer or a multilayer.

Various circuit elements such as the transistors T and the storage capacitor Cst, and various wires connected to the circuit elements may be disposed on the buffer layer BFL. In some embodiments, the buffer layer BFL may be omitted, and in this case, at least one circuit element and/or wire may be directly disposed on a surface of the substrate SUB.

Each transistor T may include a semiconductor pattern SCL (also referred to as a “semiconductor layer” or “active layer”), a gate electrode GE, and first and second transistor electrodes TE1 and TE2. FIG. 16 to FIG. 18 illustrate an embodiment in which each transistor T includes the first and second transistor electrodes TE1 and TE2 formed separately from the semiconductor pattern SCL, but the disclosure is not limited thereto. For example, in another embodiment, the first and/or second transistor electrodes TE1 and/or TE2 provided in at least one transistor T may be integrated with each semiconductor pattern SCL.

The semiconductor pattern SCL may be disposed on the buffer layer BFL. For example, the semiconductor pattern SCL may be disposed between the substrate SUB on which the buffer layer BFL is formed and a gate insulating layer GI. The semiconductor pattern SCL may include a first area contacting each first transistor electrode TE1, a second area contacting each second transistor electrode TE2, and a channel area disposed between the first and second areas. In some embodiments, one of the first and second areas may be a source area, and the other thereof may be a drain area.

In some embodiments, the semiconductor pattern SCL may be a semiconductor pattern made of polysilicon, amorphous silicon, an oxide semiconductor, or the like. The channel area of the semiconductor pattern SCL may be an intrinsic semiconductor as a semiconductor pattern that is not doped with impurities, and each of the first and second areas of the semiconductor pattern SCL may be a semiconductor pattern doped with predetermined or given impurities.

In an embodiment, the semiconductor patterns SCL of the transistors T included in each pixel circuit PXC may be made of substantially the same or similar material. For example, the semiconductor pattern SCL of the transistors T may be of at least one material of polysilicon, amorphous silicon, and an oxide semiconductor. In another embodiment, some of the transistors T may include the semiconductor patterns SCL made of different materials. For example, the semiconductor pattern SCL of some of the transistors T may be made of polysilicon or amorphous silicon, and the semiconductor pattern SCL of others of the transistors T may be made of an oxide semiconductor.

The gate insulating layer GI may be disposed on the semiconductor pattern SCL. The gate insulating layer GI may be formed as a single layer or multilayer, and may include at least one inorganic insulating material and/or organic insulating material. For example, the gate insulating layer GI may include a silicon nitride (SiNx) or a silicon oxide (SiOx), and various types of organic/inorganic insulating materials.

The gate electrode GE may be disposed on the gate insulating layer GI. FIG. 16 to FIG. 18 illustrate a top-gate structure of transistor T, but in another embodiment, the transistor T may have a bottom-gate structure. The gate electrode GE may be disposed to overlap the semiconductor pattern SCL under the semiconductor pattern SCL.

A first interlayer insulating layer ILD1 may be disposed on the gate electrode GE. For example, the first interlayer insulating layer ILD1 may be disposed between the gate electrode GE and the first and second transistor electrodes TE1 and TE2. The first interlayer insulating layer ILD1 may be formed as a single layer or multilayer, and may include at least one inorganic insulating material and/or organic insulating material. For example, the first interlayer insulating layer ILD1 may include a silicon nitride (SiNx) or a silicon oxide (SiOx), and various types of organic/inorganic insulating materials, and the materials included in the first interlayer insulating layer ILD1 are not particularly limited.

The first and second transistor electrodes TE1 and TE2 may be disposed on each semiconductor pattern SCL with at least one first interlayer insulating layer ILD1 therebetween. For example, the first and second transistor electrodes TE1 and TE2 may be disposed on different end portions of the semiconductor pattern SCL with the gate insulating layer GI and the first interlayer insulating layer ILD1 therebetween. The first and second transistor electrodes TE1 and TE2 may be electrically connected to each semiconductor pattern SCL. For example, the first and second transistor electrodes TE1 and TE2 may be connected to the first and second areas of the semiconductor pattern SCL through respective contact holes passing through the gate insulating layer GI and the first interlayer insulating layer ILD1. In some embodiments, one of the first and second transistor electrodes TE1 and TE2 may be a source electrode, and the other thereof may be a drain electrode.

At least one transistor T provided in the pixel circuit PXC may be connected to at least one pixel electrode. For example, the first transistor T1 shown in FIG. 9 and the like may be electrically connected to the first electrode ETL1 of the corresponding pixel PXL through a contact hole (for example, the first contact hole CH1) and/or a bridge pattern BRP passing through a passivation layer PSV.

The storage capacitor Cst includes a first capacitor electrode Cst_E1 and a second capacitor electrode Cst_E2 overlapping each other. Each of the first and second capacitor electrodes Cst_E1 and Cst_E2 may be configured of a single layer or a multilayer. At least one of the first and second capacitor electrodes Cst_E1 and Cst_E2 may be disposed on the same layer as at least one electrode or the semiconductor pattern SCL configuring the first transistor T1.

For example, the first capacitor electrode Cst_E1 may be configured as a multilayer electrode that includes a lower electrode LE disposed on the same layer as the semiconductor pattern SCL of the first transistor T1, and an upper electrode UE disposed on the same layer as the first and second transistor electrodes TE1 and TE2 of the first transistor T1 and electrically connected to the lower electrode LE. The second capacitor electrode Cst_E2 may be configured as a single layer electrode that is disposed on the same layer as the gate electrode of the first transistor T1 and is disposed between the lower electrode LE and the upper electrode UE of the first capacitor electrode Cst_E1.

However, the structure and/or position of each of the first and second capacitor electrodes Cst_E1 and Cst_E2 may be variously changed. For example, in another embodiment, one of the first and second capacitor electrodes Cst_E1 and Cst_E2 may include a conductive pattern disposed on a layer different from the electrodes (for example, the gate electrode GE, and the first and second transistor electrodes TE1 and TE2) and the semiconductor pattern SCL that configure the first transistor T1. For example, the first capacitor electrode Cst_E1 or the second capacitor electrode Cst_E2 may have a single-layered or multi-layered structure including a conductive pattern disposed on a second interlayer insulating layer ILD2.

In an embodiment, at least one signal wire and/or power wire connected to each pixel PXL may be disposed on the same layer as an electrode of circuit elements included in the pixel circuit PXC. For example, the scan line Si of each pixel PXL may be disposed on the same layer as the gate electrodes GE of transistors T, and the data line Dj of each pixel PXL may be disposed on the same layer as the first and second transistor electrodes TE1 and TE2 of transistors T.

The first and/or second power wires PL1 and PL2 may be disposed on the same layer as or different layers from the gate electrodes GE or first and second transistor electrodes TE1 and TE2 of the transistors T. For example, the second power wire PL2 for supplying the second power source VSS may be disposed on the second interlayer insulating layer ILD2 to be at least partially covered by the passivation layer PSV. The second power wire PL2 may be electrically connected to the second electrode ETL2 of the light source unit LSU disposed on the passivation layer PSV through the second contact hole CH2 passing through the passivation layer PSV. However, the position and/or structure of the first and/or second power wires PL1 and PL2 may be variously changed. For example, in another embodiment, the second power line PL2 may be disposed on the same layer as the gate electrodes GE of the transistors T or the first and second transistor electrodes TE1 and TE2 to be electrically connected to the second electrode ETL2 through at least one bridge pattern (not shown) and/or the second contact hole CH2.

The second interlayer insulating layer ILD2 may be disposed at an upper portion of the first interlayer insulating layer ILD1, and may cover the first and second transistor electrodes TE1 and TE2 and/or storage capacitor Cst disposed on the first interlayer insulating layer ILD1. The second interlayer insulating layer ILD2 may be formed as a single layer or multilayer, and may include at least one inorganic insulating material and/or organic insulating material. For example, the second interlayer insulating layer ILD2 may include a silicon nitride (SiNx) or a silicon oxide (SiOx), and various types of organic/inorganic insulating materials, and the materials included in the second interlayer insulating layer ILD2 are not particularly limited. The bridge pattern BRP, the first power wire PL1, and/or the second Power wire PL2 for connecting at least one circuit element (for example, the first transistor T1) provided in the pixel circuit PXC to the first electrode ETL1 may be disposed on the second interlayer insulating layer ILD2.

However, in some embodiments, the second interlayer insulating layer ILD2 may be omitted. The bridge pattern BRP of FIG. 18 may be omitted, and the second power wire PL2 may be disposed on a layer in which an electrode of the transistor T is disposed.

The passivation layer PSV may be disposed on the circuit elements including the transistors T and the storage capacitor Cst, and/or on the wires including the first and second power wires PL1 and PL2. The passivation layer PSV may be formed as a single layer or multilayer, and may include at least one inorganic insulating material and/or organic insulating material. For example, the passivation layer PSV may include at least one organic insulating layer, and may substantially flatten a surface of the circuit layer PCL. The light emitting element layer DPL may be disposed on the passivation layer PSV.

The light emitting element layer DPL may include the electrodes ETL1 and ETL2 configuring the light source unit LSU of each pixel PXL, the light emitting elements LD, and an insulating reflective layer RFL. The light emitting element layer DPL may further selectively include the first and second contact electrodes CE1 and CE2 for more stably connecting the light emitting elements LD between the first and second electrodes ETL1 and ETL2, the first bank BNK1 for protruding an area of each of the first and second electrodes ETL1 and ETL2 upward, and/or the second bank BNK2 surrounding each light emitting area EMA.

The first bank BNK1 may be disposed on the passivation layer PSV of the circuit layer PCL. The first bank BNK1 may be formed in a separate or integral pattern. The first bank BNK1 may protrude in the third direction (Z-axis direction) on a surface of the substrate SUB on which the circuit layer PCL is formed.

The first bank BNK1 may have various shapes according to embodiments. In an embodiment, the first bank BNK1 may be formed to have an inclined surface inclined at an angle of a predetermined or given range with respect to the substrate SUB. In another embodiment, the first bank BNK1 may have a cross-section of a semicircle or semi-ellipse shape, but is not limited thereto.

The first bank BNK1 may include an insulating material including at least one inorganic material and/or an organic material. For example, the first bank BNK1 may include at least one layer of inorganic film that includes various inorganic insulating materials including a silicon nitride (SiNx) or a silicon oxide (SiOx). In another embodiment, the first bank BNK1 may include at least one layer of organic film and/or photo resist film that include various organic insulating materials, or may include a single-layered or multi-layered insulator complexly including organic/inorganic materials. For example, the material and/or pattern shape of the first bank BNK1 may be variously changed.

In an embodiment, the first bank BNK1 may function as a reflective member. For example, the first bank BNK1, along with the first and second electrodes ETL1 and ETL2 provided thereon, may function as a reflective member that guides the light emitted from each light emitting element LD in a desired direction (for example, the third direction (Z-axis direction)) to improve the light efficiency of the pixel PXL. In some embodiments, the first bank BNK1 may be omitted.

The first and second electrodes ETL1 and ETL2 included in the pixel electrodes of each pixel PXL may be disposed at the upper portion of the first bank BNK1. In some embodiments, the first and second electrodes ETL1 and ETL2 may have a shape corresponding to the first bank BNK1. For example, the first and second electrodes ETL1 and ETL2 may have respective inclined or curved surfaces corresponding to the first bank BNK1, and may protrude in the third direction (Z-axis direction). In case that the first bank BNK1 is not formed, the first and second electrodes ETL1 and ETL2 are substantially formed flat on the passivation layer PSV or have different thicknesses for each area, so that an area may protrude in the third direction (Z-axis direction) of the substrate SUB.

Each of the first and second electrodes ETL1 and ETL2 may contain at least one conductive material. For example, each of the first and second electrodes ETL1 and ETL2 may include at least one metal of various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and copper (Cu), or an alloy including the same; a conductive oxide such as an indium tin oxide (ITO), an indium zinc oxide (IZO), an indium gallium zinc oxide (IGZO), an indium tin zinc Oxide (ITZO), a zinc oxide (ZnO), an aluminum doped zinc oxide (AZO), a gallium doped zinc oxide (GZO), a zinc tin oxide (ZTO), a gallium tin oxide (GTO), and a fluorine doped tin oxide (FTO); and at least one conductive material among conductive polymers such as PEDOT, but is not limited thereto. For example, each of the first and second electrodes ETL1 and ETL2 may contain other conductive materials in addition to a carbon nanotube or graphene. For example, each of the first and second electrodes ETL1 and ETL2 may have conductivity by containing at least one of various conductive materials, but the materials included therein are not particularly limited. The first and second electrodes ETL1 and ETL2 may contain the same conductive material, or may contain different conductive materials.

The first insulating layer INS1 may be disposed on an area of the first electrode ETL1 and the second electrode ETL2. For example, the first insulating layer INS1 may be formed to cover an area of each of the first electrode ETL1 and the second electrode ETL2, and may include an opening exposing another area of each of the first electrode ETL1 and the second electrode ETL2. For example, the first insulating layer INS1 may expose an area of the first electrode ETL1 and the second electrode ETL2 on each of the first banks BNK1. In some embodiments, the first insulating layer INS1 may be omitted.

In an embodiment, the first insulating layer INS1 may be first formed to entirely cover the first electrodes ETL1 and the second electrode ETL2. After the light emitting elements LD are supplied and arranged on the first insulating layer INS1, the first insulating layer INS1 may be partially opened to expose an area of respective electrodes ETL1 and ETL2 in an area on each first bank BNK1. In another embodiment, the first insulating layer INS1 may be patterned in a form of an individual pattern that is locally disposed only under the light emitting elements LD after the light emitting elements LD are completely supplied and arranged. After the first electrode ETL1 and the second electrode ETL2 are formed, the first insulating layer INS1 may be formed to cover the first electrode ETL1 and the second electrode ETL2 to prevent the first electrode ETL1 and the second electrode ETL2 from being damaged in a subsequent process. The first insulating layer INS1 may serve to stably support each light emitting element LD.

The first insulating layer INS1 may be formed as a single layer or multilayer, and may include at least one inorganic insulating material and/or organic insulating material. For example, the first insulating layer INS1 may include various types of organic/inorganic insulating materials, including a silicon nitride (SiNx), a silicon oxide (SiOx), or an aluminum oxide (AlxOy), and the materials included in the first insulating layer INS1 are not particularly limited.

Light emitting elements LD may be supplied and aligned on the first insulating layer INS1. For example, light emitting elements LD may be supplied to the light emitting area of each pixel PXL through an inkjet method, a slit coating method, or various other methods, and the light emitting elements LD may be aligned between the first electrode ETL1 and the second electrode ETL2 with directionality by a predetermined or given alignment signal (or alignment voltage) applied to each of the first electrode ETL1 and the second electrode ETL2. In an embodiment, the light emitting elements LD may be disposed so that the first end portions EP1 and the second end portions EP2 may overlap the first electrode ETL1 and the second electrode ETL2. In another embodiment, the light emitting elements LD may be disposed so as not to overlap the first electrode ETL1 and the second electrode ETL2, but may be electrically connected to the first electrode ETL1 and the second electrode ETL2 through the contact electrodes CE1 and CE2.

The insulating reflective layer RFL may be disposed under the light emitting element LD. The insulating reflective layer RFL may be disposed to overlap the light emitting element LD in the third direction (Z-axis direction). For example, the insulating reflective layer RFL may be disposed to overlap the first end portion EP1 and the second end portion EP2 of the light emitting element LD. In an embodiment, a width WR of the first direction (X-axis direction) of the insulating reflective layer RFL may be greater than a width WL of the first direction (X-axis direction) of the light emitting element LD, but is not necessarily limited thereto. As the insulating reflective layer RFL overlaps the light emitting element LD in the third direction (Z-axis direction), the light emitted from the first end portion EP1 and the second end portion EP2 of the light emitting element LD may be reflected from the insulating reflective layer RFL disposed thereunder to be emitted in the front direction of the display panel PNL, that is, in the third direction (Z-axis direction). Accordingly, an amount of light lost to a lower portion of the display panel PNL may be minimized, so that front light output efficiency may be improved.

The insulating reflective layer RFL may be disposed between the light emitting element LD and an above-described passivation layer PSV. The insulating reflective layer RFL may be directly disposed on the passivation layer PSV to be in contact with the passivation layer PSV. The insulating reflective layer RFL may be disposed between the passivation layer PSV and the first insulating layer INS1. A surface of the insulating reflective layer RFL may be in contact with the passivation layer PSV, and another surface of the insulating reflective layer RFL may be in contact with the first insulating layer INS1. The insulating reflective layer RFL may be disposed between the first electrode ETL1 and the second electrode ETL2. In the drawing, the case in which the insulating reflective layer RFL is disposed between one end of the first electrode ETL1 and one end of the second electrode ETL2 is illustrated, but the disclosure is not necessarily limited thereto. For example, the insulating reflective layer RFL may partially extend above or below the first electrode ETL1 and the second electrode ETL2.

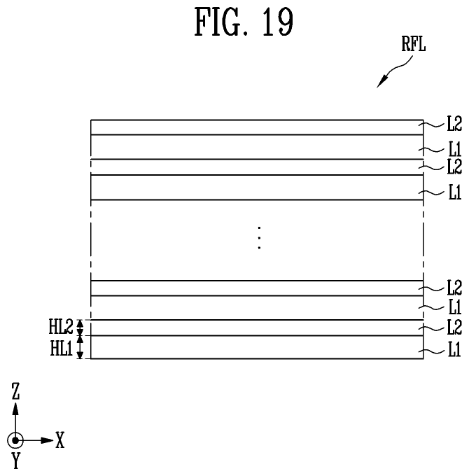

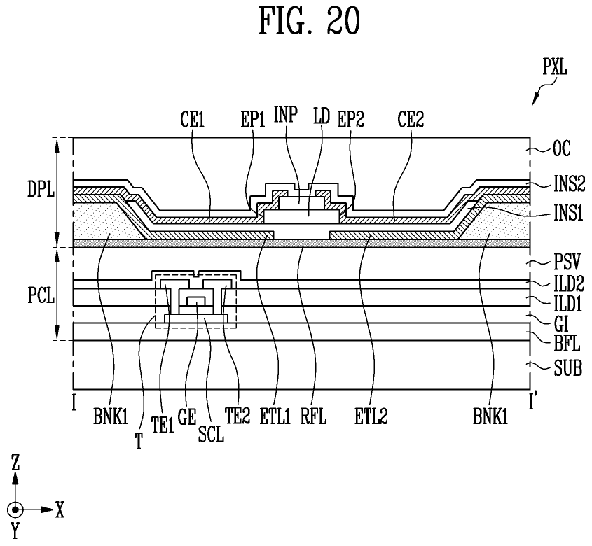

The insulating reflective layer RFL may include a reflective material having insulating properties. As the insulating reflective layer RFL may exclude a conductive material, it may be possible to prevent the insulating reflective layer RFL from affecting the alignment of the light emitting element LD. The insulating reflective layer RFL may include at least one of a barium sulfate (BaSO4), a lead carbonate (PbCO3), a titanium oxide (TiOx), a silicon oxide (SiOx), a zinc oxide (ZnOx), and an aluminum oxide (AlxOy) as a reflective material. However, the disclosure is not necessarily limited thereto, and various reflective materials may be selected within a range that may secure reflectance. In an embodiment, the insulating reflective layer RFL may be implemented as a distributed Bragg reflector (DBR). This will be described in detail with reference to FIG. 19.

FIG. 19 illustrates a schematic cross-sectional view of an insulating reflective layer according to an embodiment.

Referring to FIG. 19, the insulating reflective layer RFL may include multiple first layers L1 and second layers L2 having different refractive indexes. The first layers L1 and second layers L2 may be alternately stacked on each other. The insulating reflective layer RFL may have a structure in which five or more first layers L1 and second layers L2 are alternately stacked on each other. For example, the insulating reflective layer RFL may include 6 to 10 pairs of first layers L1 and second layers L2.

The first layer L1 and the second layer L2 may have different thicknesses. Here, the thickness of each of the layers may mean a thickness in the third direction (Z-axis direction). A thickness HL1 of the first layer L1 and a thickness HL2 of the second layer L2 may be adjusted according to a wavelength of light emitted by the light emitting element LD, respectively. For example, the thickness HL1 of the first layer L1 and the thickness HL2 of the second layer L2 may be adjusted to satisfy Equation 1 and Equation 2, respectively.

$$H L 1 = \frac{λ}{4 n 1} \qquad [ Equation 1 ]$$

$$HL 2 = \frac{λ}{4 n 2} \qquad [ Equation 2 ]$$

In Equation 1 and Equation 2, HL1 and HL2 are thicknesses of the first layer L1 and the second layer L2, respectively, A is a reflective wavelength of the insulating reflective layer RFL or a wavelength of the light emitted by the light emitting element LD, and n1 and n2 are refractive indexes of the first layer L1 and the second layer L2, respectively.

The first layer L1 and the second layer L2 may include inorganic materials having different refractive indexes. For example, each of the first layer L1 and the second layer L2 may include at least one of a silicon oxide (SiOx), a silicon nitride (SiNx), a silicon oxynitride (SiOxNy), a silicon oxycarbide (SiOxCy), a silicon carbonitride (SiCxNy), a silicon oxycarbide (SiOxCy), an aluminum oxide (AlxOy), an aluminum nitride (AlNx), a hafnium oxide (HfOx), a zirconium oxide (ZrOx), a titanium oxide (TiOx), and a tantalum oxide (TaOx). For example, the first layer L1 may include a silicon oxide (SiOx), and the second layer L2 may include a silicon nitride (SiNx). The refractive index of the first layer L1 may be smaller than the refractive index of the second layer L2, and the thickness of the first layer L1 may be greater than the thickness of the second layer L2.

Referring back to FIG. 16 to FIG. 18, an insulating pattern INP may be disposed on an area of the light emitting elements LD. For example, the insulating pattern INP may be partially disposed only on an area including a central area of each of the light emitting elements LD while exposing the first end portion EP1 and the second end portion EP2 of each of the light emitting elements LD. The insulating pattern INP may be formed as an independent pattern, but is not necessarily limited thereto. In some embodiments, the insulating pattern INP may be omitted, and in this case, the contact electrodes CE1 and CE2 may be directly disposed on the first end portion EP1 and the second end portion EP2 of the light emitting elements LD.

The insulating pattern INP may be formed as a single layer or multilayer, and may include at least one inorganic insulating material and/or organic insulating material. For example, the insulating pattern INP may include various types of organic/inorganic insulating materials, including silicon nitride (SiNx), silicon oxide (SiOx), aluminum oxide (AlxOy), and/or photo resist materials.

In case that the insulating pattern INP is formed on the light emitting elements LD after the alignment of the light emitting elements LD is completed, it may be possible to prevent the light emitting elements LD from deviating from an aligned position.

Both end portions of the light emitting elements LD that are not covered by the insulating pattern INP, that is, the first end portion EP1 and the second end portion EP2 may be covered by the first and second contact electrodes CE1 and CE2. For example, the contact electrodes CE1 and CE2 may be disposed with the insulating pattern INP interposed therebetween, and may be disposed to be spaced apart from each other on the first end portion EP1 and the second end portion EP2 of the light emitting element LD.

The contact electrodes CE1 and CE2 may be simultaneously formed on the same layer as shown in FIG. 16. Since the number of masks may be maintained, the manufacturing process of the display device may be simplified. In another embodiment, the contact electrodes CE1 and CE2 may be divided into multiple groups as shown in FIG. 17 and sequentially formed on different layers for each group. A third insulating layer INS3 may be additionally disposed between the pair of contact electrodes CE1 and CE2. That is, the position and mutual arrangement relationship of the contact electrodes CE1 and CE2 may be variously changed.

The contact electrodes CE1 and CE2 may be disposed on the first electrode ETL1 and the second electrode ETL2 to cover the exposed areas of the first electrode ETL1 and the second electrode ETL2, respectively. For example, the contact electrodes CE1 and CE2 may include the first contact electrode CE1 disposed on the first electrode ETL1 and the second electrode ETL2, and the second contact electrode CE2 disposed on the second electrode ETL2, respectively. The first contact electrode CE1 and the second contact electrode CE2 may be disposed on at least one area of the first electrode ETL1 and the second electrode ETL2 to be in contact with the first electrode ETL1 and the second electrode ETL2, respectively. Accordingly, the first contact electrode CE1 may be electrically connected to the first electrode ETL1, and the second contact electrode CE2 is electrically connected to the second electrode ETL2, so that the first electrode ETL1 and the second electrode ETL2 may be electrically connected to the first end portion EP1 and the second end portion EP2 of the light emitting element LD through the contact electrodes CE1 and CE2, respectively.

In some embodiments, the contact electrodes CE1 and CE2 may be made of various transparent conductive materials. For example, the contact electrodes CE1 and CE2 may include at least one of various transparent conductive materials including an ITO, an IZO, and an ITZO, and may be implemented to be substantially transparent or transflective to satisfy a predetermined or given light transmittance. Accordingly, the light emitted from the light emitting elements LD through the first end portion EP1 and the second end portion EP2 may pass through the contact electrodes CE1 and CE2 to be emitted to the outside of the display device.

A second insulating layer INS2 may be disposed on the contact electrodes CE1 and CE2. For example, the second insulating layer INS2 may be entirely formed on the substrate SUB to cover the first bank BNK1, the first and second electrodes ETL1 and ETL2, the light emitting elements LD, the insulating pattern INP, and the first and second contact electrodes CE1 and CE2. The second insulating layer INS2 may include at least one layer of an inorganic film and/or organic film.

In an embodiment, the second insulating layer INS2 may include a thin film encapsulation layer of a multi-layered structure. For example, the second insulating layer INS2 may include a thin film encapsulating layer of a multi-layered structure that includes at least two inorganic insulating layers and at least one organic insulating layer interposed between the at least two inorganic insulating layers, but is not necessarily limited thereto.

In some embodiments, at least one overcoat layer OC may be further disposed on the second insulating layer INS2. The overcoat layer OC may be formed as a single layer or multilayer, and may include at least one inorganic insulating material and/or organic insulating material. For example, each of the overcoat layers OC may include various types of organic/inorganic insulating materials.

According to the display device according to an above-described embodiment, the light emitted from the first end portion EP1 and the second end portion EP2 of the light emitting element LD may be reflected by the insulating reflective layer RFL under the light emitting element LD to be emitted in the front direction of the display panel PNL, that is, in the third direction (Z-axis direction). Accordingly, an amount of light lost to a lower portion of the display panel PNL may be minimized, so that front light output efficiency may be improved.

Hereinafter, a display device according to another embodiment of the disclosure will be described. The same elements as those described above will be referred to the same reference numerals in embodiments below, and redundant descriptions will be omitted or simplified.

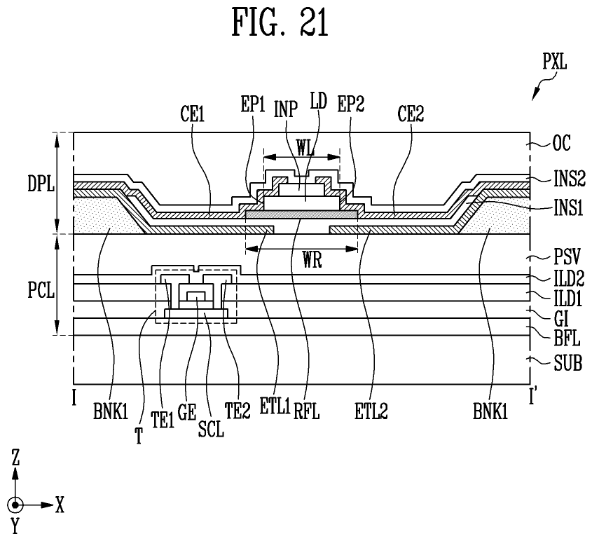

FIG. 20 illustrates a schematic cross-sectional view of a display device according to another embodiment.

Referring to FIG. 20, the pixels PXL and the display device including the same according to the embodiment may differ from embodiments of FIG. 1 to FIG. 19 at least in that the insulating reflective layer RFL may be disposed between the passivation layer PSV and the first bank BNK1.

Specifically, the insulating reflective layer RFL may be directly disposed on the passivation layer PSV, and the first bank BNK1 may be directly disposed on the insulating reflective layer RFL. For example, a surface of the insulating reflective layer RFL may be in contact with the passivation layer PSV, and another surface of the insulating reflective layer RFL may be in contact with the first bank BNK1. A surface of the insulating reflective layer RFL exposed by the first and second electrodes ETL1 and ETL2 and the first bank BNK1 may overlap the light emitting element LD in the third direction (Z-axis direction). Accordingly, the light emitted from the light emitting element LD may be reflected by the insulating reflective layer RFL to be emitted in the front direction of the display panel PNL, that is, in the third direction (Z-axis direction). That is, as described above, it may be possible to improve the front light output efficiency by minimizing an amount of light lost to a lower portion of the display panel PNL. In some embodiments, the insulating reflective layer RFL may be disposed on the front surface of the substrate SUB. Since the number of masks may be maintained, the manufacturing process of the display device may be simplified.

FIG. 21 illustrates a schematic cross-sectional view of a display device according to another embodiment.

Referring to FIG. 21, the pixels PXL and the display device including the same according to an embodiment may differ from embodiments of FIG. 1 to FIG. 19 at least in that the insulating reflective layer RFL may be disposed between the first insulating layer INS1 and the light emitting element LD.

Specifically, the insulating reflective layer RFL may be directly disposed on the first insulating layer INS1, and the light emitting element LD may be directly disposed on the insulating reflective layer RFL. For example, a surface of the insulating reflective layer RFL may be in contact with the first insulating layer INS1, and another surface of the insulating reflective layer RFL may be in contact with the light emitting element LD. The insulating reflective layer RFL may be disposed to overlap the light emitting element LD in the third direction (Z-axis direction). For example, the insulating reflective layer RFL may be disposed to overlap the first end portion EP1 and the second end portion EP2 of the light emitting element LD. The width WR of the first direction (X-axis direction) of the insulating reflective layer RFL may be greater than the width WL of the first direction (X-axis direction) of the light emitting element LD, but is not necessarily limited thereto. In case that the insulating reflective layer RFL is disposed to overlap the light emitting element LD in the third direction (Z-axis direction), the light emitted from the light emitting element LD may be reflected by the insulating reflective layer RFL to be emitted in the front direction of the display panel PNL, that is, in the third direction (Z-axis direction). That is, as described above, it may be possible to improve the front light output efficiency by minimizing an amount of light lost to a lower portion of the display panel PNL.

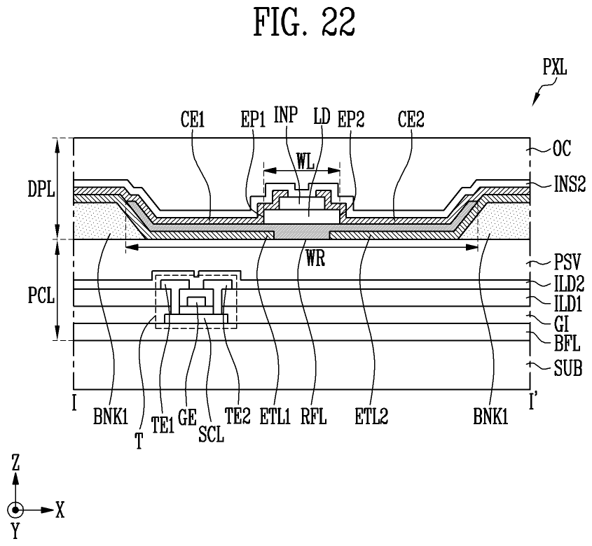

FIG. 22 illustrates a schematic cross-sectional view of a display device according to another embodiment.

Referring to FIG. 22, the pixels PXL and the display device including the same according to an embodiment may differ from embodiments of FIG. 1 to FIG. 19 at least in that a separate insulating layer disposed between the light emitting element LD and the first electrode ETL1 and the second electrode ETL2 may be omitted, and the insulating reflective layer RFL may be disposed between the light emitting element LD and the first electrode ETL1 and the second electrode ETL2.

Specifically, the insulating reflective layer RFL may be disposed to overlap the light emitting element LD on the first electrode ETL1 and the second electrode ETL2. The insulating reflective layer RFL may be directly disposed on the first electrode ETL1 and the second electrode ETL2, and the light emitting element LD may be directly disposed on the insulating reflective layer RFL. For example, a surface of the insulating reflective layer RFL may be in contact with the first electrode ETL1 and the second electrode ETL2, and another surface of the insulating reflective layer RFL may be in contact with the light emitting element LD. The insulating reflective layer RFL may be disposed to overlap the light emitting element LD in the third direction (Z-axis direction). For example, the insulating reflective layer RFL may be disposed to overlap the first end portion EP1 and the second end portion EP2 of the light emitting element LD. The width WR of the first direction (X-axis direction) of the insulating reflective layer RFL may be greater than the width WL of the first direction (X-axis direction) of the light emitting element LD, but is not necessarily limited thereto. In case that the insulating reflective layer RFL is disposed to overlap the light emitting element LD in the third direction (Z-axis direction), the light emitted from the light emitting element LD may be reflected by the insulating reflective layer RFL to be emitted in the front direction of the display panel PNL, that is, in the third direction (Z-axis direction). That is, as described above, it may be possible to improve the front light output efficiency by minimizing an amount of light lost to a lower portion of the display panel PNL.

In an embodiment, the insulating reflective layer RFL may be formed to primarily cover the first electrode ETL1 and the second electrode ETL2 entirely. After the light emitting elements LD are supplied and aligned on the insulating reflective layer RFL, they may be patterned in a form of individual patterns that are locally disposed under the light emitting elements LD. After the first electrode ETL1 and the second electrode ETL2 are formed, the insulating reflective layer RFL may be formed to cover the first electrode ETL1 and the second electrode ETL2 to prevent the first electrode ETL1 and the second electrode ETL2 from being damaged in a subsequent process. The insulating reflective layer RFL may serve to stably support each light emitting element LD. Accordingly, since a separate insulating layer disposed between the light emitting element LD and the first electrode ETL1 and the second electrode ETL2 may be omitted, the manufacturing process of the display device may be simplified.

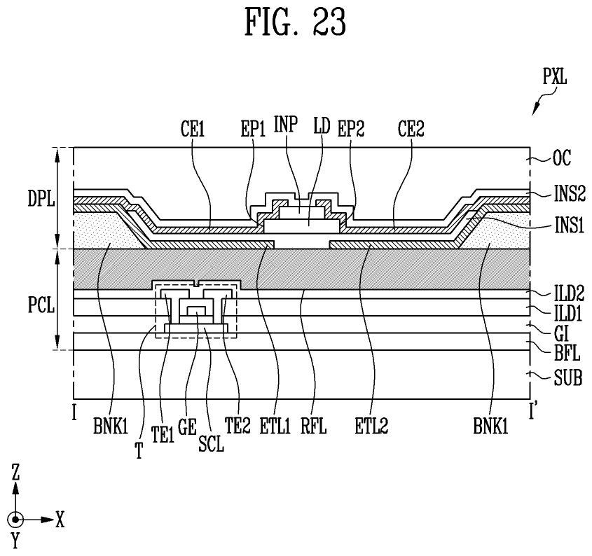

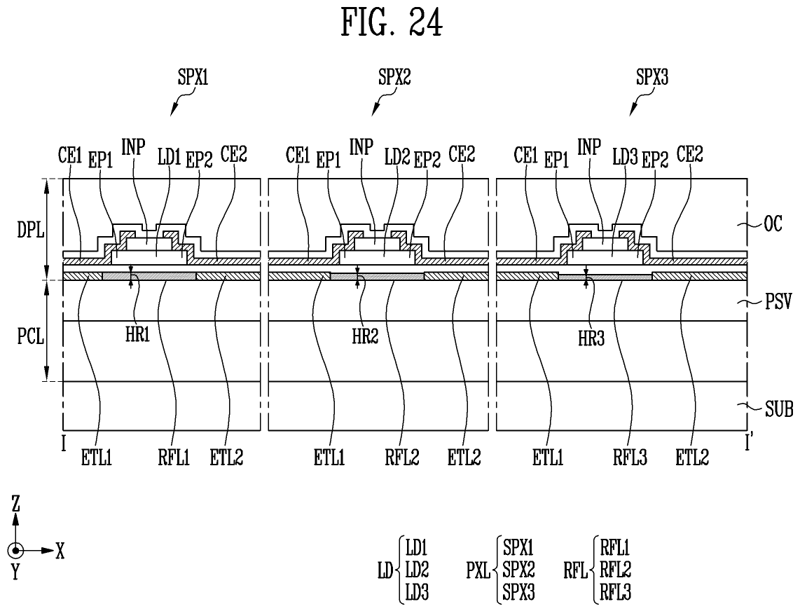

FIG. 23 illustrates a schematic cross-sectional view of a display device according to another embodiment.

Referring to FIG. 23, an embodiment may differ from embodiments of FIG. 1 to FIG. 19 at least in that the circuit layer PCL includes the insulating reflective layer RFL.

Specifically, a separate passivation layer disposed on the second interlayer insulating layer ILD2 may be omitted, and the insulating reflective layer RFL may be disposed on the second interlayer insulating layer ILD2. The insulating reflective layer RFL may be directly disposed on the second interlayer insulating layer ILD2 to be in direct contact with a surface of the second interlayer insulating layer ILD2. The insulating reflective layer RFL may be disposed to cover the circuit part including the transistor T described above.

As described above, the insulating reflective layer RFL may include multiple first layers L1 and second layers L2 having different refractive indexes. The first layers L1 and second layers L2 may be alternately stacked on each other. The first layer L1 and the second layer L2 may include inorganic materials or organic materials having different refractive indexes. For example, each of the first layer L1 and the second layer L2 may include at least one inorganic insulating material of a silicon oxide (SiOx), a silicon nitride (SiNx), a silicon oxynitride (SiOxNy), a silicon oxycarbide (SiOxCy), a silicon carbonitride (SiCxNy), a silicon oxycarbide (SiOxCy), an aluminum oxide (AlxOy), an aluminum nitride (AlNx), a hafnium oxide (HfOx), a zirconium oxide (ZrOx), a titanium oxide (TiOx), and a tantalum oxide (TaOx). The first layer L1 and the second layer L2 may include at least one organic insulating material of a polyacrylates resin, an epoxy resin, a phenolic resin, a polyamides resin, a polyimides resin, an unsaturated polyesters resin, a polyphenylenethers resin, a polyphenylenesulfides resin, and benzocyclobutene (BCB). In case that the insulating reflective layer RFL includes an organic insulating material, the insulating reflective layer RFL may serve to planarize the surface of the circuit layer PCL. Accordingly, the circuit layer PCL may omit a separate passivation layer disposed on the second interlayer insulating layer ILD2, thereby simplifying the manufacturing process of the display device.

A surface of the insulating reflective layer RFL exposed by the first and second electrodes ETL1 and ETL2 and the first bank BNK1 may overlap the light emitting element LD in the third direction (Z-axis direction). Accordingly, light emitted from the light emitting element LD may be reflected by the insulating reflective layer RFL to be emitted in the front direction of the display panel PNL, that is, in the third direction (Z-axis direction). That is, as described above, it may be possible to improve the front light output efficiency by minimizing an amount of light lost to a lower portion of the display panel PNL.

The light emitting element layer DPL may be disposed on the insulating reflective layer RFL. The description of the light emitting element layer DPL has been described with reference to FIG. 16 and the like, so duplicate contents will be omitted.

FIG. 24 illustrates a schematic cross-sectional view of a display device according to another embodiment.

In the embodiment, the detailed configuration of the circuit layer PCL excluding the passivation layer PSV is omitted and illustrated for better understanding and ease of description.

Referring to FIG. 24, the pixels PXL may include subpixels SPX, for example, a first sub-pixel SPX1, a second sub-pixel SPX2, and a third sub-pixel SPX3, respectively. In some embodiments, the first to third sub-pixels SPX1, SPX2, and SPX3 may emit light in different colors. For example, the first sub-pixel SPX1 may be a red sub-pixel emitting light in red, the second sub-pixel SPX2 may be a green sub-pixel emitting light in green, and the third sub-pixel SPX3 may be a blue sub-pixel emitting light in blue. However, the color, type, and/or number of the sub-pixels SPX1, SPX2, and SPX3 included in the pixel PXL are not particularly limited, and the color of light emitted by each of the sub-pixels SPX1, SPX2, and SPX3 may be variously changed.

The first to third light emitting elements LD1, LD2, and LD3 may emit light in different colors. For example, the first light emitting element LD1 may emit a first color, the second light emitting element LD2 may emit a second color, and the third light emitting element LD3 may emit a third color. The first color may be red light having a peak wavelength in a range of about 610 nm to about 650 nm, the second color may be green light having a peak wavelength in a range of about 510 nm to about 550 nm, and the third color may be blue light having a peak wavelength in a range of about 430 nm to about 470 nm, but the disclosure is not necessarily limited thereto.

First to third insulating reflective layers RFL1, RFL2, and RFL3 may be disposed under the first to third light emitting elements LD1, LD2, and LD3, respectively. The first to third insulating reflective layers RFL1, RFL2, and RFL3 may be disposed to overlap the first to third light emitting elements LD1, LD2, and LD3 in the third direction (Z-axis direction), respectively. Accordingly, the light emitted from the first end portion EP1 and the second end portion EP2 of each of the first to third light emitting elements LD1, LD2, and LD3 may be reflected by the first to third insulating reflective layers RFL1, RFL2, and RFL3 disposed therebelow to be emitted in the front direction of the display panel PNL, that is, in the third direction (Z-axis direction). Accordingly, as described above, it may be possible to improve the front light output efficiency by minimizing an amount of light lost to a lower portion of the display panel PNL.

The first to third reflective layers RFL1, RFL2, and RFL3 may be implemented as a distributed Bragg reflector (DBR), as described above. The thicknesses HR1, HR2, and HR3 of the first to third reflective layers RFL may be adjusted according to wavelengths of light emitted by the first to third light emitting elements LD1, LD2, and LD3, respectively. Specifically, the thicknesses HR1, HR2, and HR3 of the first to third reflective layers RFL may be proportional to wavelengths of light emitted by the first to third light emitting elements LD1, LD2, and LD3. For example, in case that the first to third light emitting elements LD1, LD2, and LD3 emit light of different colors, the first to third reflective layers RFL may have different thicknesses. For example, in case that the first light emitting element LD1 emits red light, the second light emitting element LD2 emits green light, and the third light emitting element LD3 emits blue light, the thickness HR1 of the first insulating reflective layer RFL1 may be formed to be the thickest, and the thickness HR3 of the third insulating reflective layer RFL3 may be formed to be the thinnest. The thickness HR2 of the second insulating reflective layer RFL2 may have a value between the thickness HR1 of the first insulating reflective layer RFL1 and the thickness HR3 of the third insulating reflective layer RFL3.

Those skilled in the art related to the embodiments will readily appreciate that many modifications are possible without materially departing from the novel teachings and advantages. All such modifications should be considered within the scope of the disclosure. The embodiments should be considered in a descriptive sense only and not for purposes of limitation.

What is claimed is:

1. A display device comprising:
a substrate including a plurality of pixels;
a plurality of transistors disposed on the substrate;
a passivation layer overlapping the plurality of transistors;
a first electrode and a second electrode that are disposed on the passivation layer and spaced apart from each other;
an insulating layer disposed on the first electrode and the second electrode;
a plurality of light emitting elements disposed between the first electrode and the second electrode on the insulating layer and electrically connected to the first electrode and the second electrode; and
an insulating reflective layer disposed between the passivation layer and the plurality of light emitting elements.

2. The display device of claim 1, wherein
the insulating reflective layer is disposed between the passivation layer and the insulating layer.

3. The display device of claim 1, wherein
a surface of the insulating reflective layer is in physical contact with the passivation layer, and
another surface of the insulating reflective layer is in physical contact with the insulating layer.

4. The display device of claim 1, further comprising:
a bank disposed between the passivation layer and the first electrode and the second electrode,
wherein the insulating reflective layer is disposed between the passivation layer and the bank.

5. The display device of claim 1, wherein
the insulating reflective layer is disposed on a front surface of the passivation layer.

6. The display device of claim 1, wherein
the insulating reflective layer is disposed between the insulating layer and the plurality of light emitting elements.

7. The display device of claim 1, wherein
the plurality of light emitting elements are directly disposed on the insulating reflective layer.

8. The display device of claim 1, wherein
the insulating reflective layer includes a plurality of first layers and second layers having different refractive indexes, and
the plurality of first layers and second layers are alternately stacked on each other.

9. The display device of claim 8, wherein
the plurality of first layers and second layers have different thicknesses.

10. The display device of claim 8, wherein
the plurality of first layers includes a silicon oxide (SiOx), and the plurality of second layers includes a silicon nitride (SiNx).

11. The display device of claim 8, wherein
the insulating reflective layer includes five or more of the plurality of first layers and five or more of the plurality of second layers.

12. The display device of claim 1, wherein
the insulating reflective layer includes at least one of a barium sulfate (BaSO4), a lead carbonate (PbCO3), a titanium oxide (TiOx), a silicon oxide (SiOx), a zinc oxide (ZnOx), and an aluminum oxide (AlxOy).

13. The display device of claim 1, wherein
the plurality of light emitting elements include:
a first light emitting element emitting a first color;
a second light emitting element emitting a second color; and
a third light emitting element emitting a third color.

14. The display device of claim 13, wherein
the insulating reflective layer includes:
a first insulating reflective layer disposed under the first light emitting element;
a second insulating reflective layer disposed under the second light emitting element; and
a third insulating reflective layer disposed under the third light emitting element, and
the first to third insulating reflective layers have different thicknesses.

15. The display device of claim 14, wherein
the first color is red,
the second color is green, and
the third color is blue.

16. The display device of claim 15, wherein
a thickness of the first insulating reflective layer is thicker than a thickness of the third insulating reflective layer.

17. A display device comprising:
a substrate including a plurality of pixels;
a plurality of transistors disposed on the substrate;
a passivation layer overlapping the plurality of transistors;
a first electrode and a second electrode that are disposed on the passivation layer and spaced apart from each other;
an insulating reflective layer disposed on the first electrode and the second electrode; and
a plurality of light emitting elements disposed between the first electrode and the second electrode on the insulating reflective layer and electrically connected to the first electrode and the second electrode, wherein
the insulating reflective layer includes a plurality of first layers and second layers having different refractive indexes, and
the plurality of first layers and the second layers are alternately stacked on each other.

18. The display device of claim 17, wherein
the insulating reflective layer is directly disposed on the first electrode and the second electrode.

19. The display device of claim 17, wherein
the plurality of light emitting elements are directly disposed on the insulating reflective layer.

20. A display device comprising:
a substrate including a plurality of pixels;
a plurality of transistors disposed on the substrate;
an insulating reflective layer overlapping the plurality of transistors;
a first electrode and a second electrode that are disposed on the insulating reflective layer and spaced apart from each other; and
a plurality of light emitting elements disposed between the first electrode and the second electrode and electrically connected to the first electrode and the second electrode, wherein
the insulating reflective layer includes a plurality of first layers and second layers having different refractive indexes, and
the plurality of first layers and second layers are alternately stacked on each other.

21. The display device of claim 20, wherein
the plurality of first layers and the plurality of second layers include an organic insulating material.
